(19) United States
(12) Patent Application Publication
(10) Pub. No.: US 2024/0321735 A1
(43) Pub. Date: Sep. 26, 2024

(54) SEMICONDUCTOR DEVICE

(71) Applicant: Samsung Electronics Co., Ltd., Suwon-si (KR)

(72) Inventors: Seungbo KO, Suwon-si (KR); Sujin KANG, Suwon-si (KR); Jongmin KIM, Suwon-si (KR); Donghyuk AHN, Suwon-si (KR); Jiwon OH, Suwon-si (KR); Chansic YOON, Suwon-si (KR); Myeongdong LEE, Suwon-si (KR); Minyoung LEE, Suwon-si (KR); Inho CHA, Suwon-si (KR)

(73) Assignee: Samsung Electronics Co., Ltd., Suwon-si (KR)

(21) Appl. No.: 18/601,467

(22) Filed: Mar. 11, 2024

(30) Foreign Application Priority Data
Mar. 24, 2023 (KR) 10-2023-0038967
May 22, 2023 (KR) 10-2023-0065882

(51) Int. Cl. H01L 23/528; H10B 12/00

(52) U.S. Cl. CPC H01L 23/528; H10B 12/00

(57) ABSTRACT

A semiconductor device includes a substrate, a word line extending on the substrate in a first horizontal direction, a bit line extending on the substrate in a second horizontal direction perpendicular to the first horizontal direction, and a spacer structure on one sidewall of the bit line, wherein the bit line includes a lower conductive layer, an intermediate conductive layer, and an upper conductive layer stacked in a vertical direction on the substrate, and the spacer structure includes a depletion stopping layer on one sidewall of the lower conductive layer, extending in the vertical direction and including a material layer having an interfacial trap density less than an interfacial trap density of a silicon nitride layer, and an inner spacer extending in the vertical direction and on one sidewall of the depletion stopping layer.

### CROSS-REFERENCE TO RELATED APPLICATION

This application is based on and claims priority under 35 USC § 119 to Korean Patent Application Nos. 10-2023-0038967, filed on Mar. 24, 2023, and 10-2023-0065882, filed on May 22, 2023, in the Korean Intellectual Property Office, the disclosures of which are incorporated by reference herein in their entireties.

### BACKGROUND

The inventive concepts relate to semiconductor devices, and more particularly, to semiconductor devices including a conductive line.

In semiconductor devices, such as dynamic random access memory (DRAM), circuit features have become thinner to increase data storage capacity. For example, the pitch of conductive lines (e.g., bit lines) of semiconductor devices has been decreased and a distance between the conductive lines has been also decreased. Accordingly, it may be difficult to uniformly form a vertical profile of conductive lines in semiconductor devices without damage.

### SUMMARY

The inventive concepts provide a semiconductor device including conductive lines with a vertical profile of more uniformly formed without damage.

According to an aspect of the inventive concepts, a semiconductor device may include a substrate, a word line extending in a first horizontal direction on the substrate, a bit line extending in a second horizontal direction perpendicular to the first horizontal direction on the substrate, and a spacer structure on one sidewall of the bit line, wherein the bit line includes a lower conductive layer, an intermediate conductive layer, and an upper conductive layer stacked in a vertical direction on the substrate, and the spacer structure includes a depletion stopping layer on one sidewall of the lower conductive layer, extending in the vertical direction, and including a material layer having an interfacial trap density less than an interfacial trap density of a silicon nitride layer, and an inner spacer extending in the vertical direction and on one sidewall of the depletion stopping layer.

According to another aspect of the inventive concepts, a semiconductor device may include a substrate, a word line extending in a first horizontal direction on the substrate, a bit line extending in a second horizontal direction perpendicular to the first horizontal direction on the substrate, and a spacer structure on one sidewall of the bit line, wherein the bit line includes a lower conductive layer, an intermediate conductive layer, and an upper conductive layer stacked in a vertical direction on the substrate, and the spacer structure includes a depletion stopping layer on one sidewall of the lower conductive layer, extending in the vertical direction, and including a material layer having an interfacial trap density less than an interfacial trap density of a silicon nitride layer, a passivation layer extending in the vertical direction and on a portion of one sidewall of the upper conductive layer, and an inner spacer on one sidewall of the passivation layer and on one sidewall of the depletion stopping layer, and extending in the vertical direction.

According to another aspect of the inventive concepts, a semiconductor device may include a substrate, a word line extending in a first horizontal direction on the substrate, a bit line extending in a second horizontal direction perpendicular to the first horizontal direction on the substrate, and a spacer structure on one sidewall of the bit line, wherein the spacer structure includes a depletion stopping layer on one sidewall of the lower conductive layer and extending in the vertical direction, and including a material layer having an interfacial trap density less than an interfacial trap density of a silicon nitride layer, an inner spacer in the vertical direction and on one sidewall of the depletion stopping layer, and a passivation layer extending in the vertical direction one on one sidewall of the inner spacer, one sidewall of the intermediate conductive layer, and one sidewall of the upper conductive layer.

### BRIEF DESCRIPTION OF THE DRAWINGS

Example embodiments will be more clearly understood from the following detailed description taken in conjunction with the accompanying drawings in which:

FIG. 1 is a plan view illustrating a semiconductor device according to an example embodiment;

FIG. 2 is a schematic layout diagram illustrating main components of a cell center region of a semiconductor device according to an example embodiment;

FIG. 3 is a schematic layout diagram illustrating main components of a cell center region and a cell edge region of a semiconductor device according to an example embodiment;

FIG. 4A is a cross-sectional view of a cell center region of a semiconductor device according to an example embodiment;

FIG. 4B is a partially enlarged view of FIG. 4A;

FIG. 5A is a cross-sectional view of a cell center region of a semiconductor device according to an example embodiment;

FIG. 5B is a partially enlarged view of FIG. 5A;

FIG. 6A is a cross-sectional view of a cell center region of a semiconductor device according to an example embodiment;

FIG. 6B is a partially enlarged view of FIG. 6A;

FIGS. 7A to 7E are cross-sectional views illustrating a method of manufacturing a portion of a semiconductor device according to an example embodiment;

FIGS. 8A to 8E are cross-sectional views illustrating a method of manufacturing a portion of a semiconductor device according to an example embodiment;

FIGS. 9A to 9E are cross-sectional views illustrating a method of manufacturing a portion of a semiconductor device according to an example embodiment;

FIGS. 10A to 10C are cross-sectional views illustrating a method of manufacturing a portion of a semiconductor device according to an example embodiment;

FIGS. 11A to 11C are cross-sectional views illustrating a method of manufacturing a portion of a semiconductor device according to an example embodiment;

FIGS. 12A to 12C are cross-sectional views illustrating a method of manufacturing a portion of a semiconductor device according to an example embodiment; and

FIGS. 13A to 13C are cross-sectional views illustrating a method of manufacturing a portion of a semiconductor device according to an example embodiment.

### DETAILED DESCRIPTION

Hereinafter, some example embodiments are described for example with reference to the accompanying drawings. The following example embodiments may be implemented as only one, and also, the following example embodiments may be implemented in combination of one or more. Therefore, the inventive concepts should not be construed as being limited to the disclose example embodiments.

In this specification, singular forms of elements may include plural forms unless the context clearly indicates otherwise. In this specification, the drawings are exaggerated in order to more clearly describe the inventive concepts.

As used herein, expressions such as “at least one of,” when preceding a list of elements, modify the entire list of elements and do not modify the individual elements of the list. Thus, for example, both “at least one of A, B, or C” and “at least one of A, B, and C” mean either A, B, C or any combination of two or more of A, B, and C. Likewise, A and/or B means A, B, or A and B.

While the term “same” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the terms “about” or “substantially” is used in this specification in connection with a numerical value, it is intended that the associated numerical value includes a manufacturing or operational tolerance (e.g., ±10%) around the stated numerical value. Moreover, when the word “generally” or “substantially” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

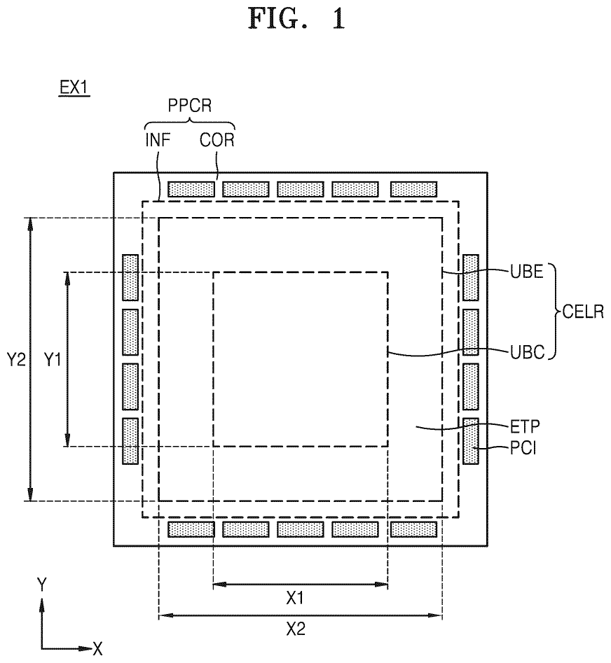

FIG. 1 is a plan view illustrating a semiconductor device EX1 according to an example embodiment.

For example, the semiconductor device EX1 may include a cell region CLER and a peripheral circuit region PPCR surrounding the cell region CELR planarly (e.g., when viewed in a plan view). The cell region CELR may include a cell center region UBC and a cell edge region UBE surrounding the cell center region UBC planarly.

The cell edge region UBE may be located on one side of the cell center region UBC in a first horizontal direction (an X direction). The cell edge region UBE may be located on one side of the cell center region UBC in a second horizontal direction (a Y direction). The cell center region UBC and the cell edge region UBE also may be referred to as a unit block center region and a unit block edge region, respectively.

The cell region CELR may have a length X2 and a length Y2 in the first horizontal direction (the X direction) and the second horizontal direction (the Y direction), respectively. The length X2 and length Y2 may be several mm to several tens of mm. In the cell region CELR, the cell center region UBC may have lengths of X1 and Y1 in the first horizontal direction (the X direction) and the second horizontal direction (the Y direction), respectively. In the cell region CLER, a region excluding the cell center region UBC may be the cell edge region UBE.

In some example embodiments, the length of the cell edge region UBE may be 5% or less of the length of the cell region CELR. For example, the cell edge region UBE may have a length (X2−X1) obtained by subtracting the length X1 of the cell center region UBC in the first horizontal direction (the X direction) from the length X2 of the cell region CLER in the first horizontal direction (the X direction). The length X2−X1 may be less than or equal to 5% of the length X1. The cell edge region UBE may have a length (Y2−Y1) obtained by subtracting the length Y1 of the cell center region UBC in the second horizontal direction (the Y direction) from the length Y2 of the cell region CELR in the second horizontal direction (the Y direction). The length Y2−Y1 may be less than or equal to 5% of the length Y1.

The peripheral circuit region PPCR may include an interface region INF surrounding the cell region and a core region COR surrounding the interface region INF planarly (e.g., when viewed in a plan view). A peripheral circuit PCI may be located in the core region COR.

The semiconductor device EX1 may be a memory device. Accordingly, the cell region CELR described above may be a memory cell region. The memory device may be a volatile memory device, such as dynamic random access memory (DRAM).

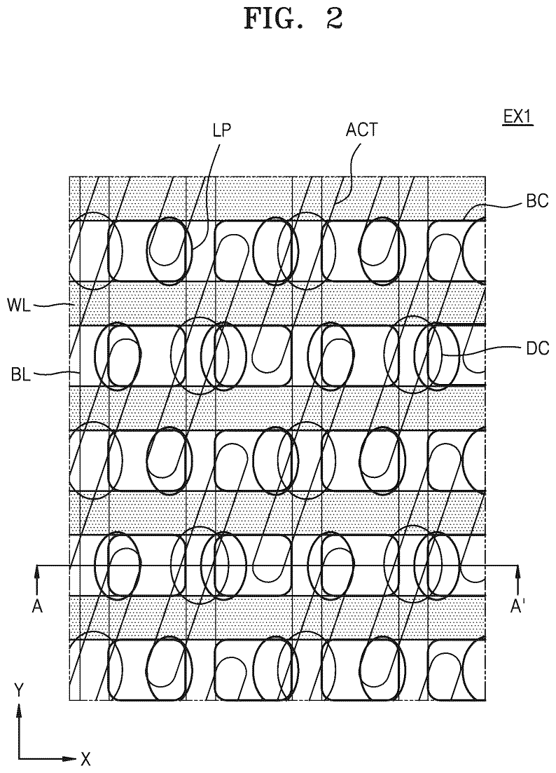

FIG. 2 is a schematic layout diagram illustrating main components of the cell center region of the semiconductor device EX1 according to an embodiment.

For example, the semiconductor device EX1 may include a plurality of active regions ACT. The active regions ACT may be located in an oblique direction with respect to the first horizontal direction (the X direction) and the second horizontal direction (the Y direction).

A plurality of word lines WL may extend to be parallel to each other in the first horizontal direction (the X direction) across the active regions ACT. A plurality of bit lines BL may extend to be parallel to each other in the second horizontal direction (the Y direction) crossing the first horizontal direction (the X direction) on the word lines WL. The bit lines BL may be connected to the active regions ACT through direct contacts DC.

A plurality of buried contacts BC may be formed between two bit lines BL adjacent to each other among the bit lines BL. In some example embodiments, the buried contacts BC may be arranged in a line in the first horizontal direction (the X direction) and the second horizontal direction (the Y direction).

A plurality of conductive landing pads LP may be formed on the buried contacts BC. The buried contacts BC and the conductive landing pads LP may serve to connect a lower electrode (not shown) of a capacitor formed on the bit lines BL to the active region ACT. At least a portion of each of the conductive landing pads LP may vertically overlap the buried contact BC.

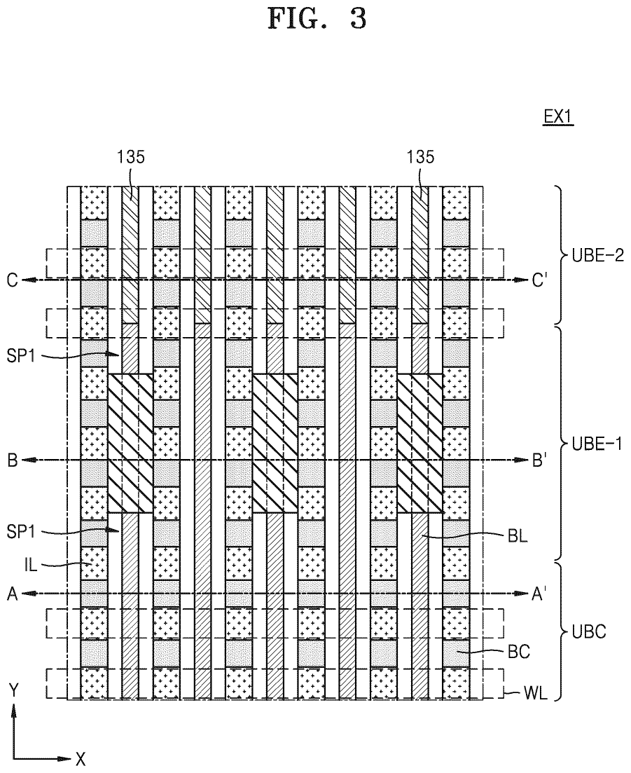

FIG. 3 is a schematic layout diagram illustrating main components of the cell center region and the cell edge region of the semiconductor device EX1 according to an example embodiment.

For example, with reference to FIG. 3, the description given above with reference to FIG. 2 is briefly given or omitted. As shown in FIG. 1, the semiconductor device EX1 may include the cell center region UBC and cell edge region UBE The cell edge region UBE may be located on one side of the cell center region UBC in the second horizontal direction (the Y direction).

The cell edge region UBE may include a first cell edge region UBE-1 and a second cell edge region UBE-2. The first cell edge region UBE-1 may be a region in which the bit line BL extends in the second horizontal direction (the Y direction). The second cell edge region UBE-2 may be a region in which the bit line BL does not extend in the second horizontal direction (the Y direction). In FIG. 3, line A-A′, line B-B′, and line C-C′ may refer to cross-sectional lines traversing the cell center region UBC, the first cell edge region UBE-1, and the second cell edge region UBE-2, respectively, in the first horizontal direction (the X direction).

As shown in FIG. 2, the semiconductor device EX1 may include the word lines WL and the bit lines BL. The word lines WL may extend in the first horizontal direction (the X direction) and may be apart from each other in the second horizontal direction (the Y direction). In FIG. 3, some word lines WL in the second horizontal direction (the Y direction) are not shown to reduce the complexity of the drawing.

The bit lines BL may extend in the second horizontal direction (the Y direction) and may be apart from each other in the first horizontal direction (the X direction). The bit line BL may extend from the cell center region UBC to the first cell edge region UBE-1 in the second horizontal direction (the Y direction).

The bit line BL may be connected to a bit line contact BLC (not shown) in the first cell edge region UBE-1 in the second horizontal direction (the Y direction). The bit line BL may be connected to an insulating pattern 135 (or an insulating line) in the second cell edge region UBE-2 in the second horizontal direction (the Y direction). A spacer structure SP1 may be located on one side of the bit line BL.

As described above with reference to FIG. 2, the bit line BL may be connected to the active regions ACT through the direct contact DC. As described above with reference to FIG. 2, the buried contacts BC may be formed between two adjacent bit lines BL among the bit lines BL.

The buried contacts BC may be arranged in a row between a pair of adjacent bit lines BL in the second horizontal direction (the Y direction). A plurality of insulating fences IL may be located between the buried contacts BC arranged in a row in the second horizontal direction (the Y direction), respectively. The buried contacts BC may be insulated from each other by the insulating fences IL. In some example embodiments, the buried contact BC also may be insulated from the bit line BL by an insulating fence IL. In some example embodiments, the insulating fences IL may include a silicon nitride layer.

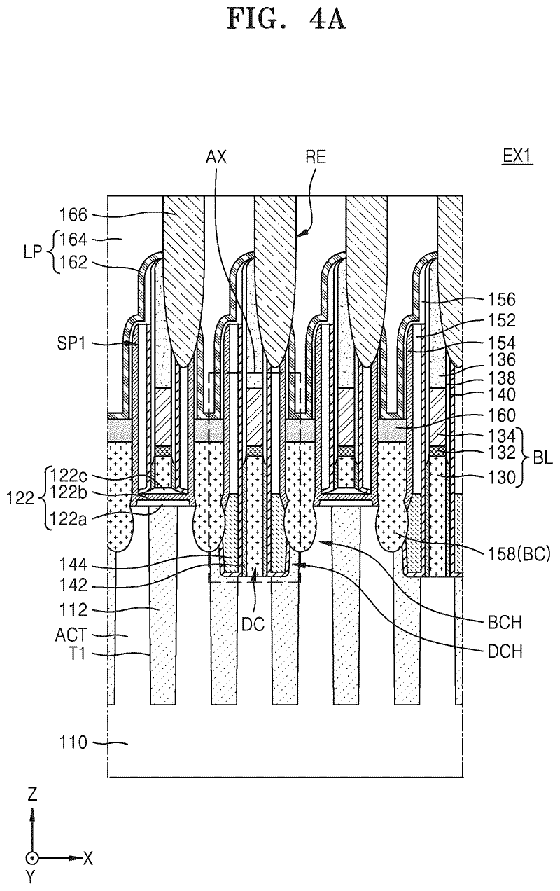

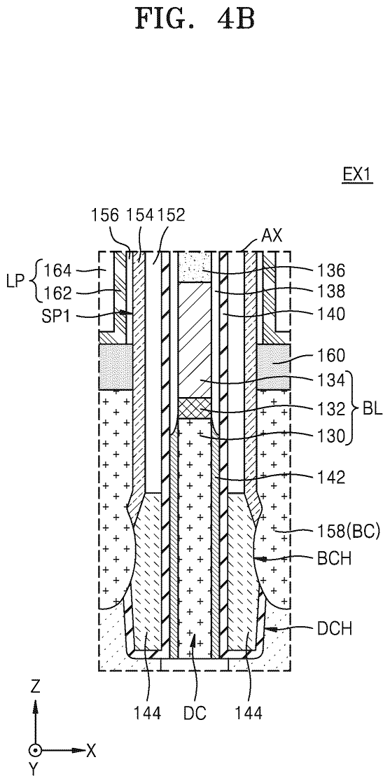

FIG. 4A is a cross-sectional view of a cell center region of a semiconductor device according to an example embodiment, and FIG. 4B is a partially enlarged view of FIG. 4A.

For example, FIG. 4A may be a cross-sectional view of some components of the cell center region UBC corresponding to the line A-A′ of FIGS. 2 and 3. FIG. 4B may be an enlarged cross-sectional view of a portion corresponding to the dashed line region indicated by “AX” in FIG. 4A.

The semiconductor device EX1 includes a substrate 110 in which the active region ACT is defined by an isolation film 112. The device isolation film 112 is formed in a device isolation trench T1 formed in the substrate 110.

The substrate 110 may include silicon, for example, monocrystalline silicon, polycrystalline silicon, or amorphous silicon. In some example embodiments, the substrate 110 may include at least one selected from Ge, SiGe, SiC, GaAs, InAs, and InP. In some implementations, the substrate 110 may include conductive regions, such as a well doped with impurities or a structure doped with impurities. The device isolation film 112 may include an oxide film, a nitride film, or combinations thereof.

FIG. 4A is not a cross-section taken along the word line (WL in FIGS. 2 and 3), and the word line extending in the first horizontal direction (the X direction) of the substrate 110 is not shown. The word line (WL of FIGS. 2 and 3) may include a gate dielectric film and a gate conductive layer formed in a word line trench in the first horizontal direction (the X direction) of the substrate 110.

The gate dielectric film may include at least one selected from a silicon oxide film, a silicon nitride film, a silicon oxynitride film, an oxide/nitride/oxide (ONO) film, or a high-k dielectric film having a dielectric constant higher than that of the silicon oxide film. The word line (WL in FIGS. 2 and 3) may include Ti, TIN, Ta, TaN, W, WN, TiSiN, WsiN, or combinations thereof.

A buffer layer 122 is formed on the substrate 110. The buffer layer 122 may be formed on upper surfaces of the active regions ACT and an upper surface of the device isolation film 112. In some example embodiments, the buffer layer 122 may include a first silicon oxide film 122a, a silicon nitride film 122b, and a second silicon oxide film 122c sequentially formed on the substrate 110.

In some example embodiments, the first silicon oxide film 122a may not be formed in the buffer layer 122 according to a manufacturing process. In this case, the buffer layer 122 may include the silicon nitride film 122b and the second silicon oxide film 122c.

In some example embodiments, the first silicon oxide film 122a and the second silicon oxide film 122c may not be formed in the buffer layer 122 according to a manufacturing process. In this case, the buffer layer 122 may include the silicon nitride film 122b.

The bit lines BL extending to be parallel to each other in the second horizontal direction (the Y direction) are formed on the buffer layer 122. In some example embodiments, the bit line BL may be formed on a silicon oxide film or a silicon nitride film according to a material forming the buffer layer 122.

The bit lines BL are apart from each other in the first horizontal direction (the X direction). Each of the bit lines BL may be connected to the active region ACT through the direct contact DC.

The direct contact DC is formed on a partial region of each of the active regions ACT. The direct contact DC is buried in a direct contact hole DCH exposing the active region ACT of the substrate 110. The direct contact DC may be buried in the substrate 110 such that a lower end portion of the direct contact DC is located at a level lower than that of the upper surface of the substrate 110.

In some example embodiments, the direct contact DC may include a polysilicon film doped with impurities, such as boron (B), arsenic (As), or phosphorus (P). In some example embodiments, the direct contact DC may include Si, Ge, W, WN, Co, Ni, Al, Mo, Ru, Ti, TiN, Ta, TaN, Cu, or combinations thereof.

Each of the bit lines BL may include a lower conductive layer 130, an intermediate conductive layer 132, and an upper conductive layer 134 sequentially formed on the substrate 110. Each of the bit lines BL is covered with an insulating capping pattern 136. In the vertical direction (the Z direction), the insulating capping pattern 136 may be located on the upper conductive layer 134. An upper surface of the lower conductive layer 130 and an upper surface of the direct contact DC may be located on the same plane.

Although the bit lines BL are illustrated as having a triple conductive layer structure including the lower conductive layer 130, the intermediate conductive layer 132, and the upper conductive layer 134 in FIG. 4, the inventive concepts are not limited thereto. For example, the bit lines BL may include a single conductive layer or a stacked structure of a plurality of conductive layers including double conductive layers, quadruple conductive layers, or more.

In some example embodiments, the lower conductive layer 130 may include a polysilicon film doped with impurities, such as boron (B), arsenic (As), or phosphorus (P). In some example embodiments, the intermediate conductive layer 132 may include a barrier metal layer. In some example embodiments, the upper conductive layer 134 may include a metal layer.

In some example embodiments, the intermediate conductive layer 132 and upper conductive layer 134 may include a film including Ti, TiN, TiSiN, tungsten (W), WN, tungsten silicide (Wsix), tungsten silicon nitride (WsixNy), ruthenium (Ru), or a film including combinations thereof.

For example, the intermediate conductive layer 132 may include a TiN film and/or a TiSiN film, and the upper conductive layer 134 may include tungsten (W). In some example embodiments, the insulating capping pattern 136 may include a silicon nitride film.

A plurality of buried contact plugs 158 may be located on the substrate 110. The buried contact plug 158 may correspond to the buried contact BC of FIGS. 2 and 3. The buried contact plug 158 may have a column shape extending in a vertical direction (a Z direction) in a space between each of the bit lines BL. Each of the buried contact plugs 158 may contact the active region ACT.

The buried contact plugs 158 are buried in the buried contact hole BCH exposing the active region ACT of the substrate 110. The buried contact plugs 158 may be buried in the substrate 110 such that lower end portions of the buried contact plugs 158 are located at a level lower than that of the upper surface of the substrate 110. The buried contact plugs 158 may include a semiconductor material doped with impurities, such as boron (B), arsenic (As), or phosphorus (P), a metal, a conductive metal nitride, or combinations thereof, but are not limited thereto.

In the semiconductor device EX1, one direct contact DC and a pair of buried contact plugs 158 facing each other with the one direct contact DC therebetween may be connected to different active regions ACT among the active regions ACT. The buried contact plugs 158 may be arranged in a row in the second horizontal direction (the Y direction).

The semiconductor device EX1 may include a plurality of spacer structures SP1 between the bit lines BL and the buried contact plugs 158. One spacer structure SP1 may be located between one bit line BL and the buried contact plugs 158 arranged in a row in the second horizontal direction (the Y direction). Each of the spacer structures SP1 may include a passivation layer 138, a depletion stopping layer 142, an inner spacer 140, an intermediate spacer 152, and an outer spacer 154.

The depletion stopping layer 142 may contact each of a sidewall of the direct contact DC and a sidewall of the lower conductive layer 130 of the bit line BL. The depletion stopping layer 142 may be a material layer serving to block or prevent depletion of the direct contact DC or the lower conductive layer 130 of the bit line BL. The depletion stopping layer 142 may include a material layer having an interfacial trap density less than that of a silicon nitride layer.

In some example embodiments, the depletion stopping layer 142 may include a silicon oxide layer. In some example embodiments, when the depletion stopping layer 142 includes a silicon oxide layer, the interfacial trap density may be reduced by about 90% compared to that of the silicon nitride layer. For example, the interfacial trap density of the silicon nitride layer is 6.28 E12 (eV/cm²), whereas the interfacial trap density of the silicon oxide layer may be reduced to 5.4 E12 (eV/cm²).

As described below, when the inner spacer 140 is formed, the depletion stopping layer 142 may be formed. In some example embodiments, the inner spacer 140 may include a silicon oxide layer. In some example embodiments, the inner spacer 140 may include a carbon-containing oxide layer (SiOC).

In some example embodiments, when the direct contact DC or the lower conductive layer 130 of the bit line BL includes a polysilicon layer doped with impurities, such as boron, arsenic, or phosphorus, the depletion stopping layer 142 may be a silicon oxide layer formed by oxidizing a polysilicon layer.

According to an example embodiment of the inventive concepts, when the direct contact DC and the lower conductive layer 130 of the bit line BL each includes a polysilicon layer doped with impurities, the depletion stopping layer 142 in contact with each of the sidewall of the lower conductive layer 130 and the sidewall of the direct contact may include a silicon oxide layer.

In the semiconductor device EX1 according to an example embodiment of the inventive concepts, a depletion region may be mitigated or prevented from being formed in the lower conductive layer 130 and the direct contact DC in the vicinity of an interface between the lower conductive layer 130 and the depletion stopping layer 142 and an interface between the direct contact DC and the depletion stopping layer 142. Accordingly, the electrical characteristics of the lower conductive layer 130 and the direct contact DC may be mitigated or prevented from being deteriorated. Thus, in the semiconductor device EX1 according to an example embodiment of the inventive concepts, the conductive line, for example, the bit line or the direct contact DC, may be more uniformly formed without damage.

The depletion stopping layer 142 may be apart from the buried contact plug 158 with the inner spacer 140, the intermediate spacer 152, and the outer spacer 154 therebetween. In the vertical direction (the Z direction), an upper surface (or one sidewall of an upper portion) of the depletion stopping layer 142 may be formed to be inclined from the uppermost surface of the lower conductive layer 130 or the direct contact DC. In other words, the uppermost surface of the depletion stopping layer 142 may not have the same plane as that of the uppermost surface of the lower conductive layer 130 or the direct contact DC.

The passivation layer 138 may contact a sidewall of each of the intermediate conductive layer 132 and the upper conductive layer 134 and a sidewall of the insulating capping pattern 136. The passivation layer 138 may be formed on the depletion stopping layer 142 in the vertical direction (the Z direction). In some example embodiments, the passivation layer 138 may include a silicon nitride layer.

A gap-fill insulating pattern 144 may be located between a lower end portion of the contact plug 158 and the direct contact DC to cover the sidewall of the lower end portion of the buried contact plug 158 and the sidewall of the direct contact DC. In some example embodiments, the gap-fill insulating pattern 144 may include a silicon nitride layer. In some example embodiments, the gap-fill insulating pattern 144 may include a carbon-containing oxide layer (SiOC).

The sidewall and bottom surface of the gap-fill insulating pattern 144 may be surrounded by the inner spacer 140. The depletion stopping layer 142 and the inner spacer 140 may each include a portion located between the direct contact DC and the gap-fill insulating pattern 144. The depletion stopping layer 142 may be apart from the buried contact plug 158 with the inner spacer 140 and the gap-fill insulating pattern 144 therebetween.

The intermediate spacer 152 may cover a sidewall of the bit lines BL adjacent thereto. The intermediate spacer 152 may be located between the inner spacer 140 and the outer spacer 154. In some example embodiments, the intermediate spacer 152 may include a silicon oxide layer.

The outer spacer 154 may cover the sidewall of the bit line BL adjacent thereto. The outer spacer 154 may extend in the vertical direction (the Z direction) to cover the sidewall of adjacent bit lines BL with the passivation layer 138, the inner spacer 140, and the intermediate spacer 152 therebetween. In some example embodiments, the outer spacer 154 may include a silicon nitride layer. The depletion stopping layer 142, the passivation layer 138, the intermediate spacer 152, and the outer spacer 154 may each extend to be parallel to the bit line BL in the second horizontal direction (the Y direction).

A metal silicide film 160 and a plurality of conductive landing pads LP may be sequentially formed on each of the buried contact plugs 158. In some embodiments, an insulating spacer 156 may be further formed between the conductive landing pad LP and the spacer structure SP1. The conductive landing pads LP may be connected to the buried contact plugs 158 through the metal silicide film 160.

The conductive landing pads LP may extend from a space between each of the insulating capping patterns 136 to an upper portion of each of the insulating capping patterns 136 to vertically overlap a portion of the bit lines BL. Each of the conductive landing pads LP may include a conductive barrier layer 162 and a conductive layer 174.

In some example embodiments, the metal silicide film 160 may include cobalt silicide, nickel silicide, or manganese silicide, but example embodiments are not limited to the above example. In some example embodiments, the metal silicide film 160 may be omitted. The conductive barrier layer 162 may have a Ti/TiN stack structure.

The conductive layer 164 may include doped polysilicon, metal, metal silicide, conductive metal nitride, or combinations thereof. In some example embodiments, the conductive layer 164 may include tungsten (W). As shown in FIG. 2, the conductive landing pads LP may have a plurality of island-like pattern shapes in a plan view. The conductive landing pads LP may be electrically insulated from each other by an insulating layer 166 filling a separation space RE therearound.

In the semiconductor device EX1 as described above, consumption of the lower conductive layer of the bit line or the direct contact may be reduced during a manufacturing process by forming the depletion stopping layer on one sidewall of the direct contact or the lower conductive layer of the bit line. Accordingly, the semiconductor device EX1 may more uniformly form a vertical profile of the conductive line, for example, the bit line BL or the direct contact DC without damage.

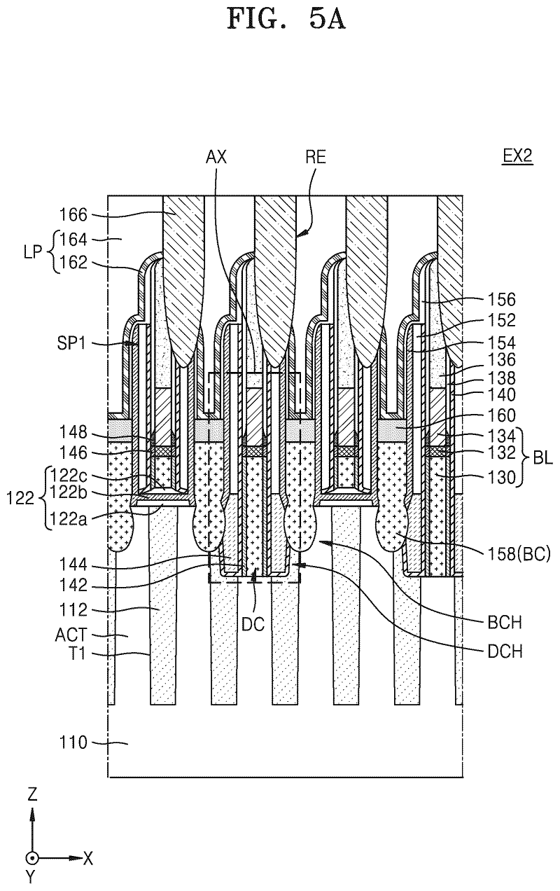

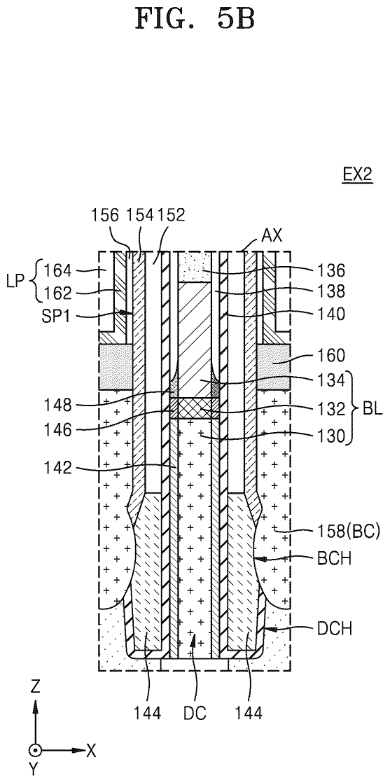

FIG. 5A is a cross-sectional view of a cell center region of a semiconductor device EX2 according to an embodiment, and FIG. 5B is a partially enlarged view of FIG. 5A.

For example, FIG. 5A may be a cross-sectional view of some components of the cell center region UBC corresponding to a cross-section taken along line A-A′ of FIGS. 2 and 3. FIG. 5B may be an enlarged cross-sectional view of a portion corresponding to the dashed line region indicated by “BX” in FIG. 5A.

The semiconductor device EX2 may be substantially the same as the semiconductor device EX1 of FIGS. 4A and 4B except that a configuration of a spacer structure SP1 is different. With reference to FIGS. 5A and 5B, the description given above with reference to FIGS. 4A and 4B is briefly given or omitted.

The semiconductor device EX2 may include a plurality of spacer structures SP1 located between the bit lines BL and the buried contact plugs 158. The spacer structures SP1 include a passivation layer 138, a depletion stopping layer 142, an inner spacer 140, metal oxide layers 146 and 148, an intermediate spacer 152, and an outer spacer 154, respectively.

In the semiconductor device EX2, the depletion stopping layer 142 may contact only the sidewall of the direct contact DC and the sidewall of the lower conductive layer 130 of the bit line BL. Metal oxide layers 146 and 148 may be formed on one sidewall of the intermediate conductive layer 132 of the bit line BL and a portion of one sidewall of the upper conductive layer 134, on the depletion stopping layer 142 in the vertical direction (the Z direction).

The metal oxide layers 146 and 148 may include a first metal oxide layer 146 formed on the sidewall of the intermediate conductive layer 132 and a second metal oxide layer 148 formed on a portion of the sidewall of the upper conductive layer 134. In some example embodiments, the first metal oxide layer 146 may be a titanium metal nitride layer or a titanium silicon nitride oxide layer. In some example embodiments, the second metal oxide layer 148 may be a tungsten oxide layer or a tungsten nitride oxide layer.

The passivation layer 138 may be formed on a sidewall of the upper conductive layer 134 and a sidewall of the insulating capping pattern 136. The passivation layer 138 may be formed on the metal oxide layers 146 and 148 in the vertical direction (the Z direction). In some example embodiments, the passivation layer 138 may include a silicon oxide layer. As described below, when the passivation layer 138 is formed, the depletion stopping layer 142 and the metal oxide layers 146 and 148 also may be formed.

In the semiconductor device EX2 as described above consumption of the depletion stopping layer 142 during a manufacturing process may be reduced by further forming the metal oxide layers 146 and 148 on one sidewall of the intermediate conductive layer 132 of the bit line BL and a portion of one sidewall of the upper conductive layer 134. Accordingly, in the semiconductor device EX2, a vertical profile of a conductive line, for example, the bit line BL or the direct contact DC, may be more uniformly formed without damage.

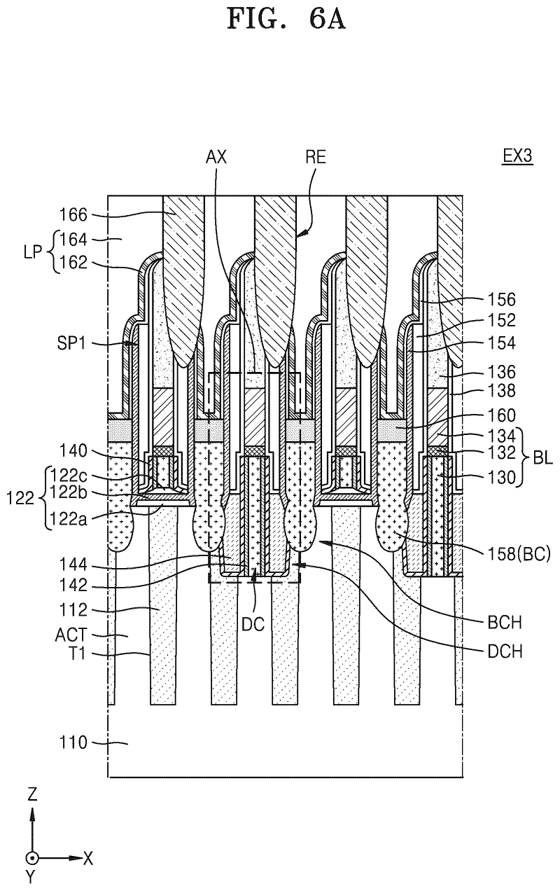

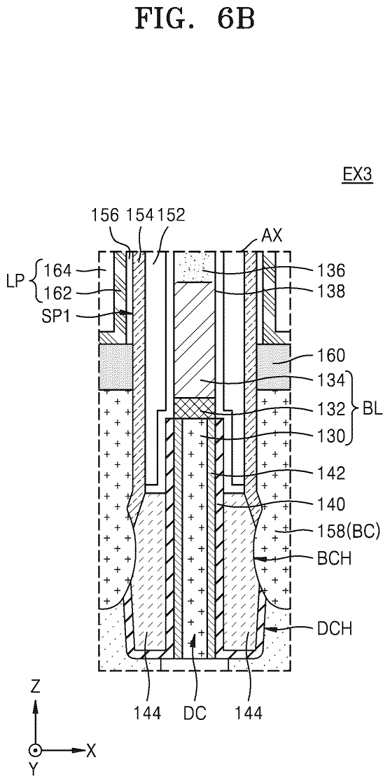

FIG. 6A is a cross-sectional view of a cell center region of a semiconductor device EX3 according to an example embodiment, and FIG. 6B is a partially enlarged view of FIG. 6A.

For example, FIG. 6A may be a cross-sectional view of some components of the cell center region UBC corresponding to a cross-section taken along line A-A′ of FIGS. 2 and 3. FIG. 6B may be an enlarged cross-sectional view of a portion corresponding to the dashed line region indicated by “CX” in FIG. 6A.

The semiconductor device EX3 may be substantially the same as the semiconductor device EX1 of FIGS. 4A and 4B except that the configuration of the spacer structure SP1 is different. With reference to FIGS. 6A and 6B, the description given above with reference to FIGS. 4A and 4B are briefly given or omitted.

The semiconductor device EX3 may include a plurality of spacer structures SP1 located between the bit lines BL and the buried contact plugs 158. Each of the spacer structures SP1 may include the passivation layer 138, the depletion stopping layer 142, the inner spacer 140, the intermediate spacer 152, and the outer spacer 154.

In the semiconductor device EX3, the depletion stopping layer 142 may contact only the sidewall of the direct contact DC and the sidewall of the lower conductive layer 130 of the bit line BL. One sidewall of the depletion stopping layer 142 may be located on an inner side than one sidewalls of the intermediate conductive layer 132 and the upper conductive layer 134. As described below, when the inner spacer 140 is formed, the depletion stopping layer 142 may be formed.

The passivation layer 138 is formed on one sidewall of the inner spacer 140, the intermediate conductive layer 132, the upper conductive layer 134, and the insulating capping pattern 136 in the vertical direction (the Z direction). The passivation layer 138 extends nonlinearly along a vertical direction (the Z direction). For example, the passivation layer 138 extends nonlinearly along a vertical direction (the Z direction) from an upper portion of one sidewall of the upper conductive layer 134 of the bit line BL towards the lower conductive layer 130 of the bit line BL. The passivation layer 138 is curved on the uppermost surface of the inner spacer 140. In some example embodiments, the passivation layer 138 may include a silicon nitride layer.

In the semiconductor device EX3 as described above, the passivation layer 138 may be further formed on one sidewall of the intermediate conductive layer 132 and the upper conductive layer 134 of the bit line BL and one sidewall of the inner spacer 140, thereby reducing consumption of the intermediate conductive layer 132, the upper conductive layer 134, and the depletion stopping layer 142 during the manufacturing process. Accordingly, in the semiconductor device EX3, a vertical profile of a conductive line, for example, the bit line BL or the direct contact DC may be formed without damage.

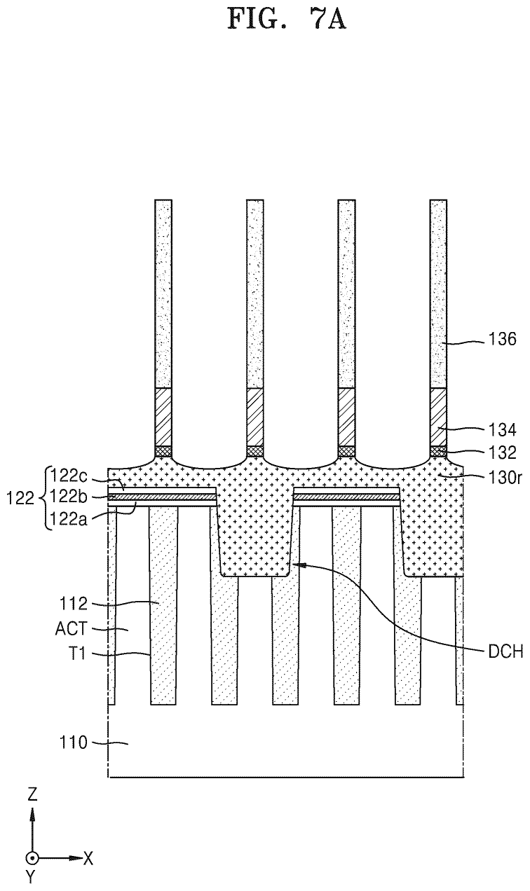

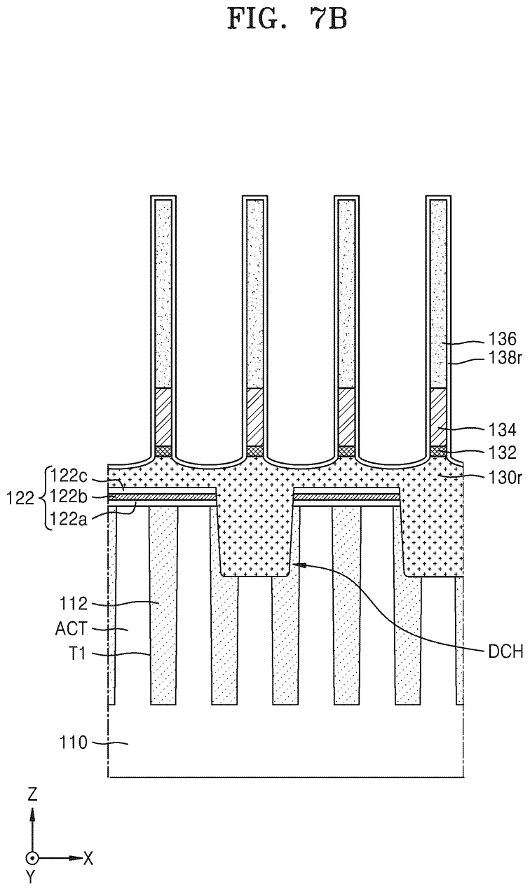

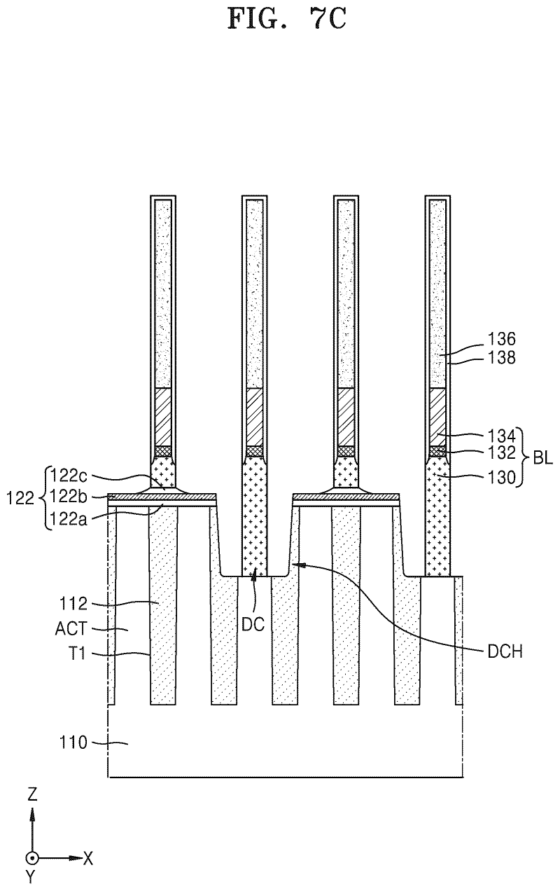

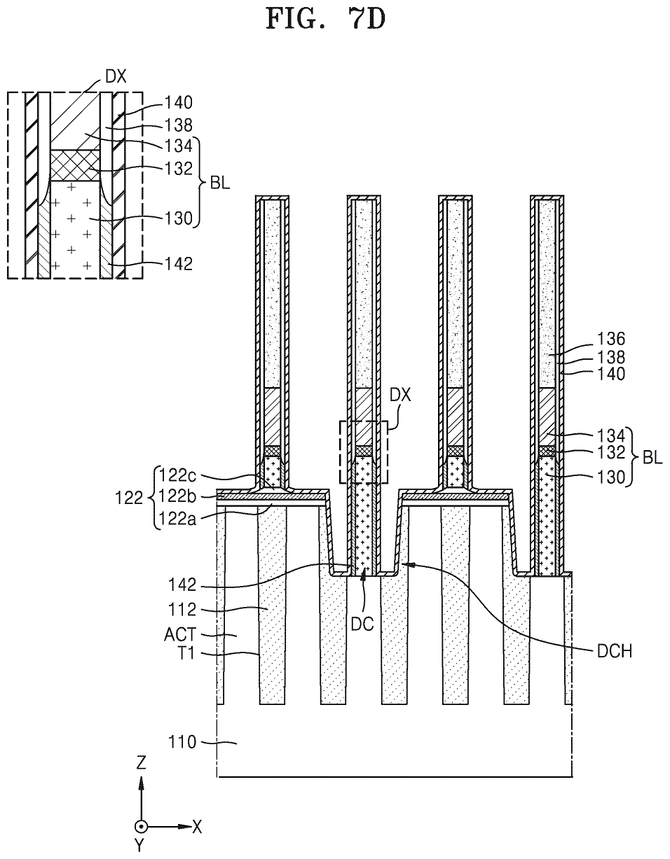

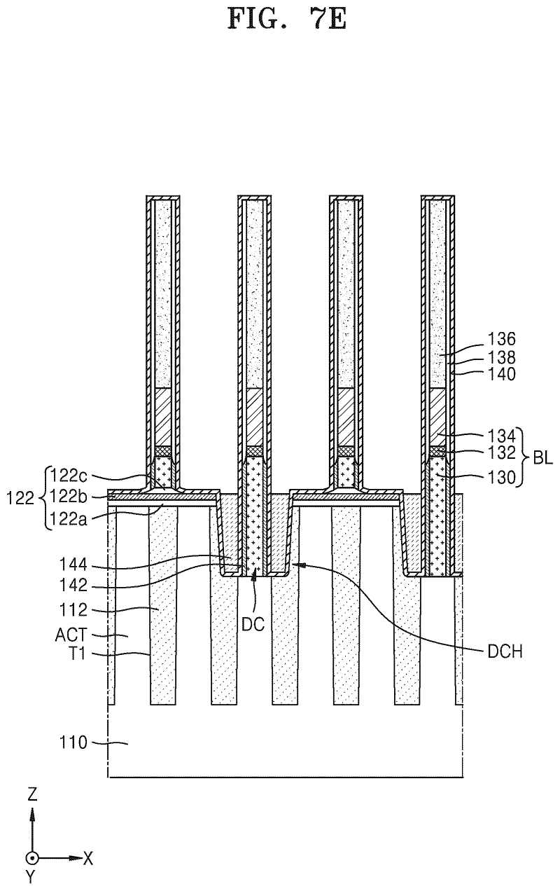

FIGS. 7A to 7E are cross-sectional views illustrating a method of manufacturing a portion of a semiconductor device according to an example embodiment.

For example, FIGS. 7A to 7E may be cross-sectional views illustrating a method of manufacturing some components corresponding to a cross-section taken along line A-A′ of FIGS. 2 and 3. FIGS. 7A to 7E are cross-sectional views illustrating a method of manufacturing a portion of the semiconductor device EX1 of FIGS. 4A and 4B. With reference to FIGS. 7A to 7E, the description given above with reference to FIGS. 4A and 4B is briefly given or omitted.

Referring to FIG. 7A, a device isolation trench T1 is formed on the substrate 110, and the device isolation film 112 is formed in the device isolation trench T1. The active regions ACT may be defined on the substrate 110 by the device isolation film 112.

The buffer layer 122 may be formed on the substrate 110. The buffer layer 122 may be formed on the upper surfaces of the active regions ACT and the upper surface of the device isolation film 112. In some example embodiments, the buffer layer 122 may include the first silicon oxide film 122a, the silicon nitride film 112b, and the second silicon oxide film 122c on the substrate 110. In some example embodiments, the buffer layer 122 may include a single film of the first silicon oxide film 122a or the second silicon oxide film 122c or a single film of the silicon nitride film 112b.

A portion of each of the buffer layer 122, the substrate 110, and the device isolation film 112 is etched to form the direct contact hole DCH exposing the active region ACT of the substrate 110. A lower conductive material layer 130r filling the direct contact hole DCH is formed on the direct contact hole DCH and the buffer layer 122, and the intermediate conductive layer 132, the upper conductive layer, and the insulating capping pattern 136 are formed on the lower conductive material layer 130r.

For example, an intermediate conductive material layer, an upper conductive material layer, and an insulating capping material layer are sequentially formed on the lower conductive material layer 130r filling the direct contact hole DCH, followed by a photolithography process on the insulating capping material layer to form a mask pattern. Subsequently, only the insulating capping material layer, the upper conductive material layer, and the intermediate conductive material layer are etched using the mask pattern as an etch mask. In this case, the lower conductive material layer 130r is left, and the intermediate conductive layer 132, the upper conductive layer 134, and the insulating capping pattern 136 are formed on the lower conductive material layer 130r.

During etching using the mask pattern, the uppermost surface of the lower conductive material layer 130r is formed to be higher than the uppermost surface of the direct contact hole DCH or the buffer layer 122. The uppermost surface of the lower conductive material layer 130r may be formed in a curved shape. In some example embodiments, the lower conductive material layer 130r includes a polysilicon film doped with impurities.

Referring to FIG. 7B, a passivation material layer 138r is formed on the lower conductive material layer 130r, the intermediate conductive layer 132, the upper conductive layer 134, and the insulating capping pattern 136. The passivation material layer 138r may be formed on a surface of the lower conductive material layer 130r, sidewalls of the intermediate conductive layer 132, the upper conductive layer 134, and the insulating capping pattern 136, and on an upper surface of the insulating capping pattern 136. In some example embodiments, the passivation material layer 138r is formed as a silicon nitride layer.

Referring to FIG. 7C, the lower conductive material layer 130r is etched using the insulating capping pattern 136 and the passivation material layer 138r as an etch mask to form the direct contacts DC and the bit lines BL on the substrate 110. After the bit lines BL are formed, a portion of the direct contact hole DCH may be exposed again around the direct contact DC.

The direct contacts DC may include the lower conductive layer 130. The bit lines BL may include the lower conductive layer 130, the intermediate conductive layer 132, and the upper conductive layer 134.

During etching for forming the direct contacts DC and the bit lines BL, the passivation material layer 138r formed on the upper surface of the insulating capping pattern 136 and the upper surface of the lower conductive material layer 130r may be etched. Accordingly, the passivation layer 138 may be formed on sidewalls of the intermediate conductive layer 132, the upper conductive layer 134, and the insulating capping pattern 136. In some example embodiments, the passivation layer 138 may also be formed on a portion of the uppermost sidewall of the lower conductive layer 130.

Referring to FIG. 7D, the left drawing of FIG. 7D may be an enlarged view of a portion corresponding to the dashed line region indicated by “DX” in the right drawing. The depletion stopping layer 142 is formed on sidewalls of the direct contacts DC and the lower conductive layer 130 of the bit lines BL, and the inner spacer 140 is formed on sidewalls of the intermediate conductive layer 132, the upper conductive layer 134, and the insulating capping pattern 136 of the bit lines BL.

The inner spacer 140 may also be formed on the upper surface of the buffer layer 122, the upper surface of the device isolation film 112, the inner wall of the direct contact hole DCH, a sidewall of the insulating capping pattern 136, and the upper surface of the passivation layer 138.

In some example embodiments, the inner spacer 140 may include a silicon oxide layer. In some example embodiments, the inner spacer 140 may include a carbon-containing oxide layer (SiOC).

The carbon-containing oxide layer may include a material having a dielectric constant less than that of the silicon oxide layer. In some example embodiments, the carbon-containing oxide layer may have a carbon atom (C) content of about 10 atom % to about 50 atom %. For example, the carbon-containing oxide layer may be represented by SixOyCz, and here, 0.1≤x≤0.5, 0.1≤y≤0.5, and 0.1≤z≤0.8, but example embodiments are not limited thereto.

The depletion stopping layer 142 may be formed by oxidizing the sidewall of the lower conductive layer 130 when the inner spacer 140 is formed. The depletion stopping layer 142 may play a role of mitigating or preventing depletion of the lower conductive layer 130 in a subsequent process. In some example embodiments, the depletion stopping layer 142 may include a material layer having an interfacial trap density less than that of the silicon nitride layer. In some example embodiments, the depletion stopping layer 142 may include a silicon oxide layer. The depletion stopping layer 142 may be formed on a sidewall of a portion of the lower conductive layer 130. The depletion stopping layer 142 may not be formed on an upper sidewall of the lower conductive layer 130.

Referring to FIG. 7E, a gap-fill insulating pattern 144 is formed inside the direct contact hole DCH. In some example embodiments, the gap-fill insulating pattern 144 may be formed by forming a gap-fill insulating material layer in the direct contact hole DCH and then etching back the gap-fill insulating material layer. The gap-fill insulating pattern 144 may be formed on the inner spacer 140 in the direct contact hole DCH.

In some example embodiments, the gap-fill insulating pattern 144 may include a silicon nitride layer. In some example embodiments, the gap-fill insulating pattern 144 may include a carbon-containing oxide layer (SiOC). The carbon-containing oxide layer (SiOC) may be a material as described above regarding the inner spacer 140.

Subsequently, the intermediate spacer (152 in FIGS. 4A and 4B) and the outer spacer (154 in FIGS. 4A and 4B) are formed on the inner spacer 140 formed on the sidewalls of the direct contact DC and the bit line BL, thereby forming the spacer structure (SP1 in FIGS. 4A and 4B).

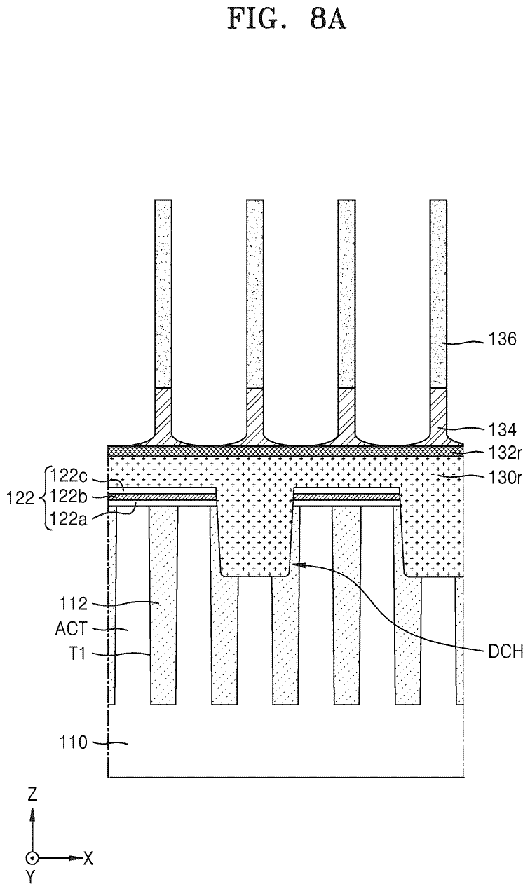

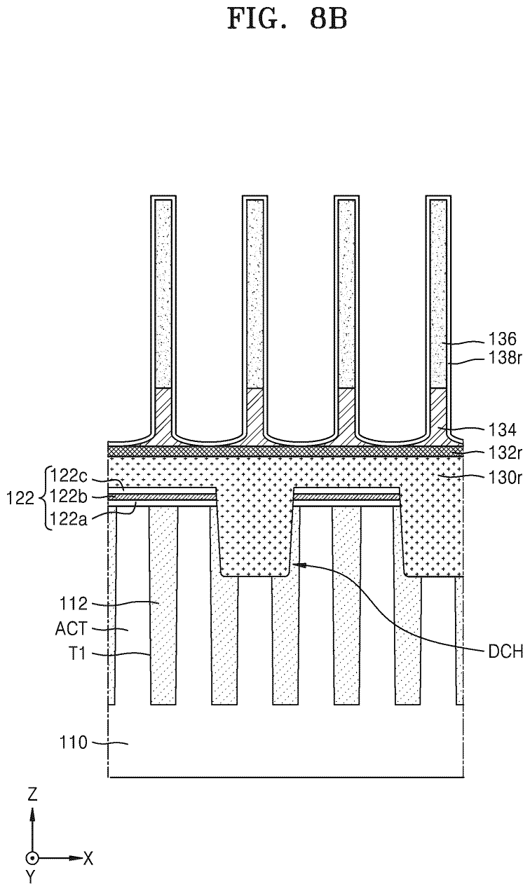

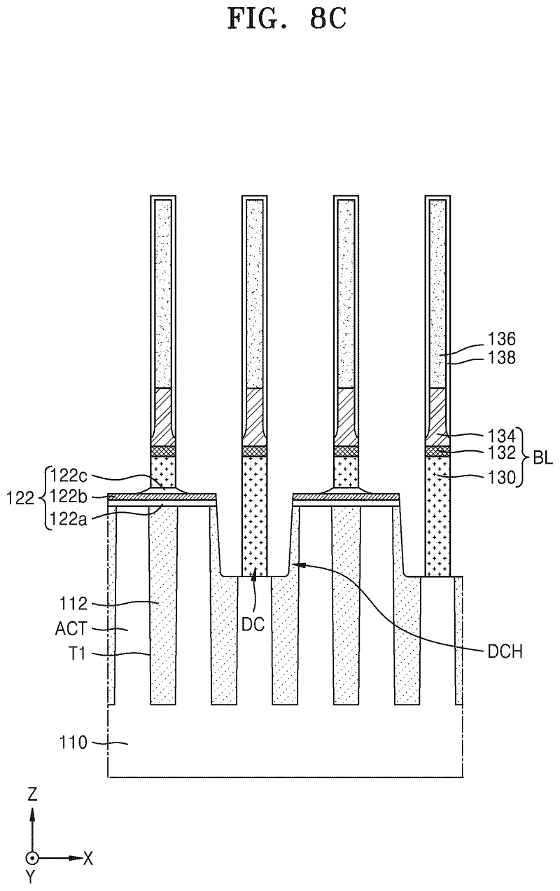

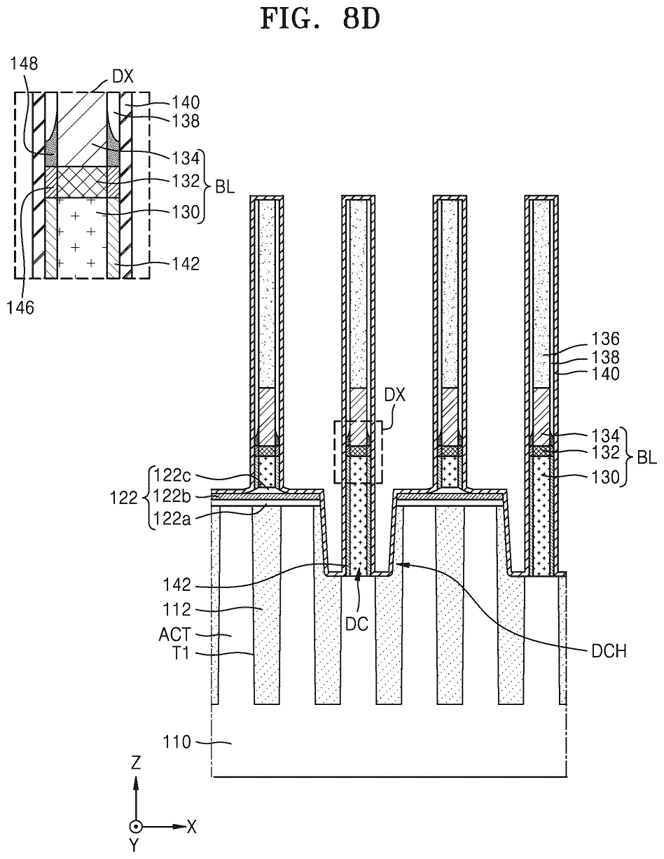

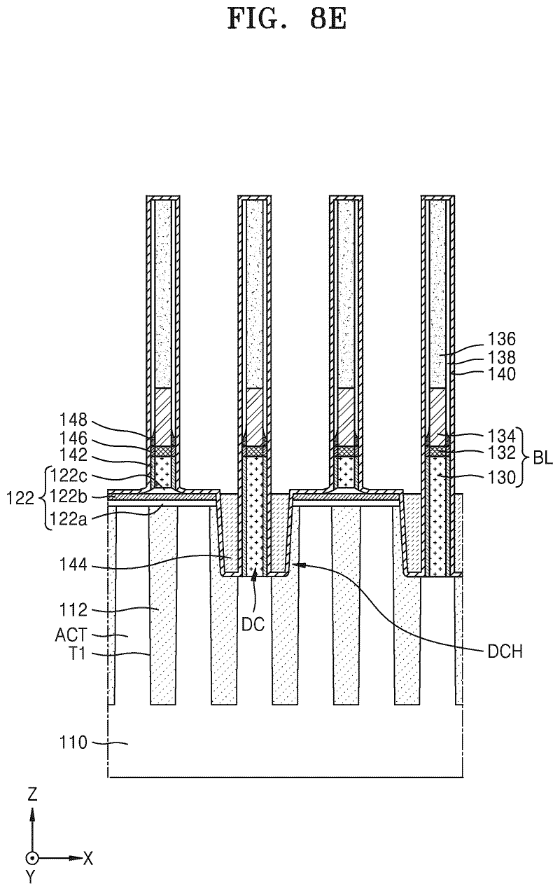

FIGS. 8A to 8E are cross-sectional views illustrating a method of manufacturing a portion of a semiconductor device according to an example embodiment.

For example, FIGS. 8A to 8E may be cross-sectional views illustrating a method of manufacturing some components corresponding to a cross-section taken along line ‘-A’ of FIGS. 2 and 3. FIGS. 8A to 8E are cross-sectional views illustrating a method of manufacturing a portion of the semiconductor device EX2 of FIGS. 5A and 5B. With reference to FIGS. 8A to 8E, the description given above with reference to FIGS. 5A and 5B and FIGS. 7A to 7E is briefly given or omitted.

Referring to FIG. 8A, the device isolation trench Tl and the device isolation film 112 are formed on the substrate 110. The active regions ACT may be defined on the substrate 110 by the device isolation film 112.

The buffer layer 122 may be formed on the substrate 110. The buffer layer 122 may be formed on upper surfaces of the active regions ACT and the upper surface of the device isolation film 112. In some embodiments, the buffer layer 122 may include a first silicon oxide film 122a, a silicon nitride film 112b, and a second silicon oxide film 122c on the substrate 110. In some example embodiments, the buffer layer 122 may be a single layer of the first silicon oxide film 122a or the second silicon oxide film 122c or a single layer of the silicon nitride film 112b.

A portion of each of the buffer layer 122, the substrate 110, and the device isolation film 112 is etched to form the direct contact hole DCH exposing the active region ACT of the substrate 110. The lower conductive material layer 130r filling the direct contact hole DCH is formed on the direct contact hole DCH and the buffer layer 122, the intermediate conductive material layer 132r, the upper conductive layer 134, and the insulating capping pattern 136 are formed on the lower conductive material layer 130r.

For example, the intermediate conductive material layer 132r, the upper conductive material layer, and the insulating capping material layer are sequentially formed on the lower conductive material layer 130r filling the direct contact hole DCH, and then a mask pattern is formed on the insulating capping material layer using a photolithography process. Subsequently, only the insulating capping material layer and the upper conductive material layer are etched using the mask pattern as an etch mask.

In this case, the lower conductive material layer 130r and the intermediate conductive material layer 132r are left, and the upper conductive layer 134 and the insulating capping pattern 136 are formed on the intermediate conductive material layer 132r. An upper portion of the upper conductive layer 134 may have a width less than that of a lower portion thereof in the vertical direction (the Z direction).

During the etching process using the mask pattern described above, the uppermost surface of the lower conductive material layer 130r is formed to be higher than the direct contact hole DCH or the uppermost surface of the buffer layer 122. The uppermost surface of the intermediate conductive material layer 132r may be formed in a flat surface shape.

In some example embodiments, the lower conductive material layer 130r is formed as a polysilicon film doped with impurities. The intermediate conductive material layer 132r and the upper conductive layer 134 may include a film including Ti, TiN, TiSiN, tungsten (W), WN, tungsten silicide (WSix), tungsten silicon nitride (WSixNy), ruthenium (Ru), or combinations thereof.

Referring to FIG. 8B, the passivation material layer 138r is formed on the intermediate conductive material layer 132r, the upper conductive layer 134, and the insulating capping pattern 136. The passivation material layer 138r may be formed on a surface of the intermediate conductive material layer 132r, an upper conductive layer 134, a sidewall of the insulating capping pattern 136, and an upper surface of the insulating capping pattern 136. In some example embodiments, the passivation material layer 138r is formed as a silicon nitride layer.

Referring to FIG. 8C, the intermediate conductive material layer 132r and the lower conductive material layer 130r are etched using the insulating capping pattern 136 and the passivation material layer 138r as an etch mask to form the direct contacts DC and the bit lines BL on the substrate 110. After the bit lines BL are formed, a portion of the direct contact hole DCH may be exposed again around the direct contact DC.

The direct contacts DC may include the lower conductive layer 130. The bit lines BL may include the lower conductive layer 130, the intermediate conductive layer 132, and the upper conductive layer 134.

During etching to form the direct contacts DC and the bit lines BL, the passivation material layer 138r may be etched to form the passivation layer 138. The passivation layer 138 may be formed on a sidewall of the upper conductive layer 134, a sidewall of the insulating capping pattern 136, and an upper surface of the insulating capping pattern 136.

Referring to FIG. 8D, the left drawing of FIG. 8D may be an enlarged view of a portion corresponding to the dashed line region indicated by “EX” in the right drawing. The depletion stopping layer 142 is formed on sidewalls of the direct contacts DC and the lower conductive layer 130 of the bit lines BL, and the metal oxide layers 146 and 148 are formed on one sidewall of the intermediate conductive layer 132 and on one sidewall (more specifically, on a bottom portion of one sidewall) of the upper conductive layer 134, respectively.

In addition, the inner spacer 140 is formed on sidewalls of the lower conductive layer 130, the intermediate conductive layer 132, the upper conductive layer 134, and the insulating capping pattern 136 of the bit lines BL. The inner spacer 140 may also be formed on an upper surface of the buffer layer 122, an upper surface of the device isolation film 112, an inner wall of the direct contact hole DCH, an upper surface of the insulating capping pattern 136, and an upper surface of the passivation layer 138.

In some example embodiments, the inner spacer 140 may include a silicon oxide layer. In some example embodiments, the inner spacer 140 may include a carbon-containing oxide layer (SiOC). The carbon-containing oxide layer may include a material having a dielectric constant less than that of the silicon oxide layer. In some example embodiments, the carbon-containing oxide layer may have a carbon atom (C) content of about 10 atom % to about 50 atom %. For example, the carbon-containing oxide layer may be represented by SixOyCz, and here, 0.1≤x≤0.5, 0.1≤y≤0.5, and 0.1≤z≤0.8, but example embodiments are not limited thereto.

The depletion stopping layer 142 may be formed by oxidizing the sidewall of the lower conductive layer 130 when the inner spacer 140 is formed. The depletion stopping layer 142 may play a role of mitigating or preventing depletion of the lower conductive layer 130 in a subsequent process.

In some example embodiments, the depletion stopping layer 142 may be formed of a material layer having a lower interfacial trap density than the silicon nitride layer. In some example embodiments, the depletion stopping layer 142 may be formed of a silicon oxide layer. The depletion stopping layer 142 may be formed on a sidewall of the lower conductive layer 130. The metal oxide layers 146 and 148 may be formed on one sidewall of the intermediate conductive layer 132 and the upper conductive layer 134 when the inner spacer 140 is formed.

Referring to FIG. 8E, the gap-fill insulating pattern 144 is formed inside the direct contact hole DCH. In some example embodiments, the gap-fill insulating pattern 144 may be formed by forming a gap-fill insulating material layer in the direct contact hole DCH and then etching back the gap-fill insulating material layer. The gap-fill insulating pattern 144 may be formed on the inner spacer 140 in the direct contact hole DCH.

In some example embodiments, the gap-fill insulating pattern 144 may include a silicon nitride layer. In some example embodiments, the gap-fill insulating pattern 144 may include a carbon-containing oxide layer (SiOC). The carbon-containing oxide layer (SiOC) may be a material as described above for the inner spacer 140.

Subsequently, an intermediate spacer (152 in FIGS. 5A and 5B) and an outer spacer (154 in FIGS. 5A and 5B) are formed on the inner spacer 140 formed on the sidewalls of the direct contact DC and the bit line BL. By forming, a spacer structure (SP1 in FIGS. 5A and 5B) is formed.

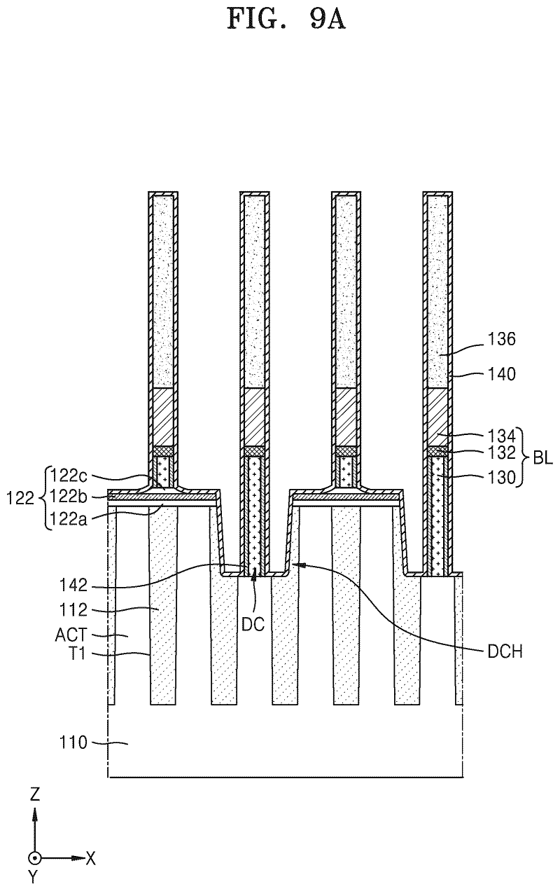

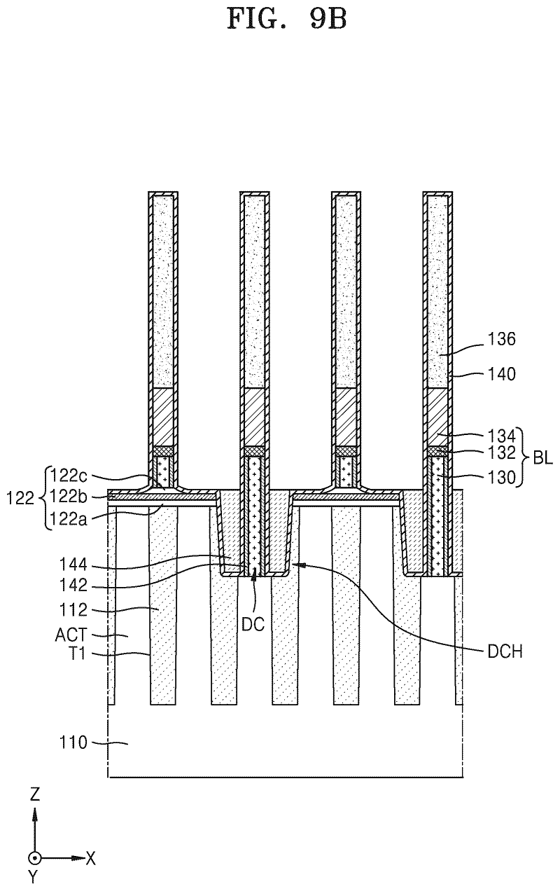

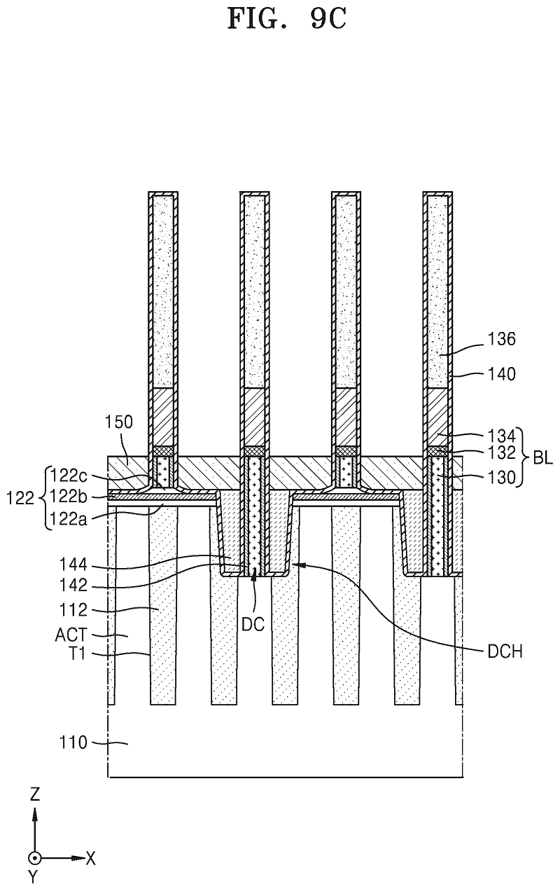

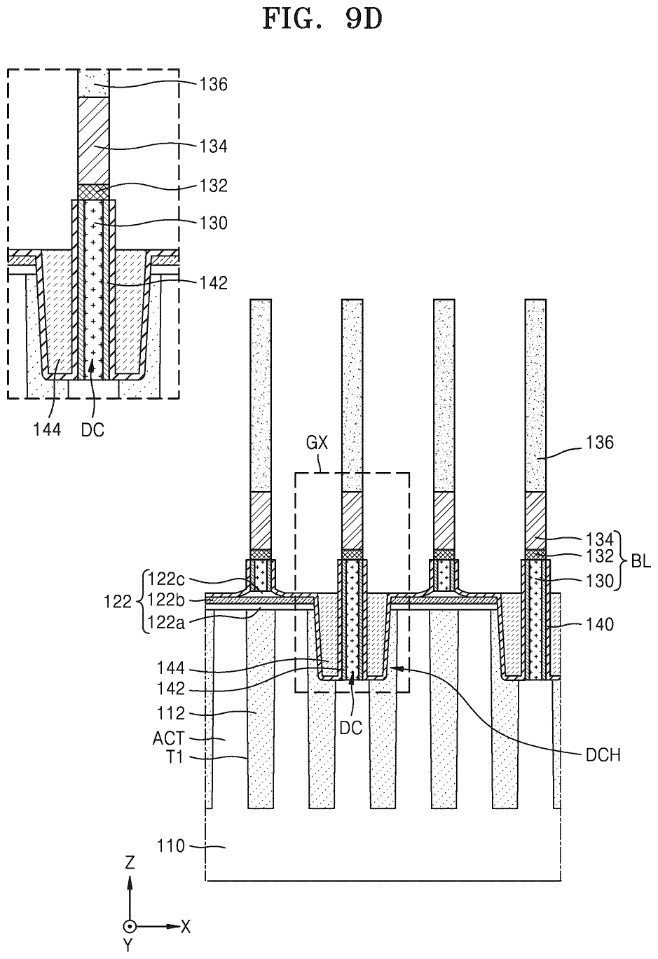

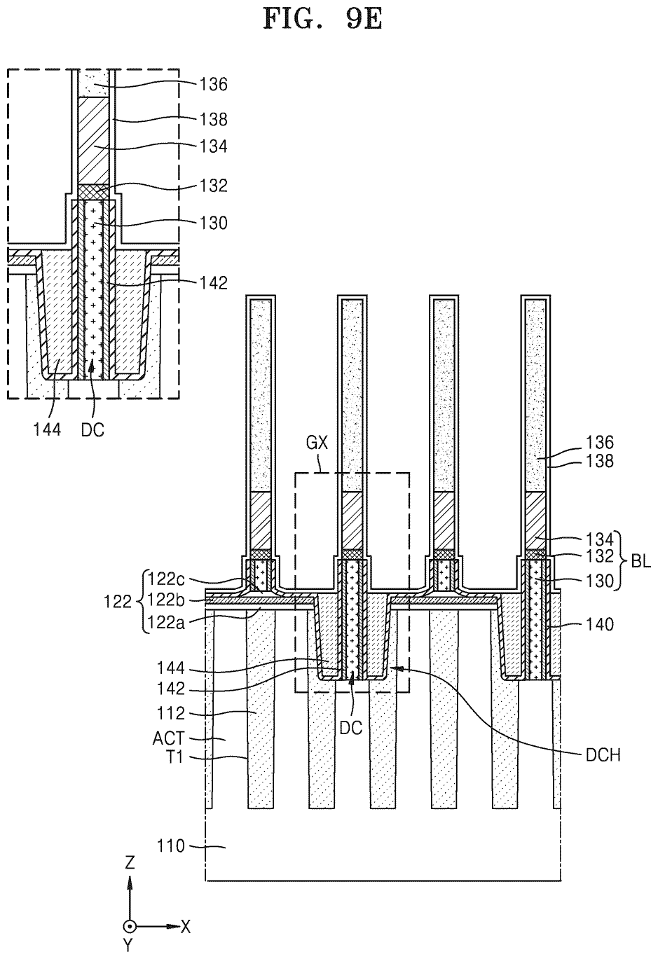

FIGS. 9A to 9E are cross-sectional views illustrating a method of manufacturing a portion of a semiconductor device according to an example embodiment.

For example, FIGS. 9A to 9E may be cross-sectional views illustrating a method of manufacturing some components corresponding to the cross-section taken along line A-A′ of FIGS. 2 and 3. FIGS. 9A to 9E are cross-sectional views illustrating a method of manufacturing a portion of the semiconductor device EX3 of FIGS. 6A and 6B. With reference to FIGS. 9A to 9E, the description given above with reference to FIGS. 6A and 6B, 7A to 7E, and 8A to 8E is briefly given or omitted.

Referring to FIG. 9A, the device isolation trench T1 and the device isolation film 112 are formed on the substrate 110. The active regions ACT may be defined on the substrate 110 by the device isolation film 112.

The buffer layer 122 may be formed on the substrate 110. The buffer layer 122 may be formed on upper surfaces of the active regions ACT and the upper surface of the device isolation film 112. In some example embodiments, the buffer layer 122 may include a first silicon oxide film 122a, a silicon nitride film 112b, and a second silicon oxide film 122c on the substrate 110. In some embodiments, the buffer layer 122 may be a single layer of the first silicon oxide film 122a or the second silicon oxide film 122c or a single layer of the silicon nitride film 112b.

A portion of each of the buffer layer 122, the substrate 110, and the device isolation film 112 is etched to form the direct contact hole DCH exposing the active region ACT of the substrate 110. The direct contact DC, the lower conductive layer 130, the intermediate conductive layer 132, the upper conductive layer 134, and the insulating capping pattern 136 are formed on the direct contact hole DCH and the buffer layer 122. The lower conductive layer 130, the intermediate conductive layer 132, and the upper conductive layer 134 constitute the bit line BL.

For example, after a lower conductive material layer filling the direct contact hole DCH is formed, an intermediate conductive material layer, an upper conductive material layer, and an insulating capping material layer are sequentially formed on the lower conductive material layer. Subsequently, a mask pattern is formed on the insulating capping material layer using a photolithography process, and then the insulating capping material layer, the upper conductive material layer, the intermediate conductive material layer, and the lower conductive material layer are sequentially etched using the mask pattern as an etch mask.

In this case, the direct contact DC, the lower conductive layer 130, the intermediate conductive layer 132, the upper conductive layer 134, and the insulating capping pattern 136 may be formed on the direct contact hole DCH and the buffer layer 122. After the direct contact DC, the lower conductive layer 130, the intermediate conductive layer 132, the upper conductive layer 134, and the insulating capping pattern 136 are formed, a portion of the direct contact hole DCH may be exposed again around the direct contact DC.

In some example embodiments, the lower conductive layer 130 is formed as a polysilicon film doped with impurities. The intermediate conductive layer 132 and upper conductive layer 134 may include a film including Ti, TiN, TiSiN, tungsten (W), WN, tungsten silicide (WSix), tungsten silicon nitride (WSixNy), ruthenium (Ru), or a film including combinations thereof.

Subsequently, the inner spacer 140 is formed on sidewalls of the direct contact DC, the lower conductive layer 130, the intermediate conductive layer 132, the upper conductive layer 134, and the insulating capping pattern 136. In some example embodiments, the inner spacers 140 may include a silicon oxide layer. In some example embodiments, the inner spacer 140 may include a carbon-containing oxide layer (SiOC).

The carbon-containing oxide layer may include a material having a dielectric constant less than that of the silicon oxide layer. In some example embodiments, the carbon-containing oxide layer may have a carbon atom (C) content of about 10 atom % to about 50 atom %. For example, the carbon-containing oxide layer may be represented by SixOyCz, and here 0.1≤x≤0.5, 0.1≤y≤0.5, and 0.1≤z≤0.8, but example embodiments are not limited thereto.

When forming the inner spacer 140, the depletion stopping layer 142 may be formed on the sidewalls of the direct contacts DC and the lower conductive layer 130. The depletion stopping layer 142 may be formed by oxidizing the sidewalls of the direct contacts DC and the lower conductive layer 130 when the inner spacer 140 is formed.

The depletion stopping layer 142 may serve to mitigate or prevent depletion of the lower conductive layer 130 in a subsequent process. In some example embodiments, the depletion stopping layer 142 may include a material layer having an interfacial trap density lower than that of the silicon nitride layer. In some example embodiments, the depletion stopping layer 142 may include a silicon oxide layer.

The inner spacer 140 may be formed on the sidewall of the depletion stopping layer 142, the sidewall of the intermediate conductive layer 132, the sidewall of the upper conductive layer 134, the sidewall of the insulating capping pattern 136, and the upper surface of the insulating capping pattern 136.

Referring to FIG. 9B, the gap-fill insulating pattern 144 is formed inside the direct contact hole DCH. In some example embodiments, the gap-fill insulating pattern 144 may be formed by forming a gap-fill insulating material layer in the direct contact hole DCH and then etching back the gap-fill insulating material layer.

In some example embodiments, the gap-fill insulating pattern 144 may include a silicon nitride layer. In some example embodiments, the gap-fill insulating pattern 144 may include a carbon-containing oxide layer (SiOC). The carbon-containing oxide layer (SiOC) may be the same material as that described above for the inner spacer 140.

The gap-fill insulating pattern 144 may be formed on the inner spacer 140 in the direct contact hole DCH. In some example embodiments, when the gap-fill insulating pattern 144 is formed, the inner spacer 140 formed on the upper surface of the insulating capping pattern 136 may be etched.

Referring to FIG. 9C, a mask layer 150 is formed on the buffer layer 122 and the gap-fill insulating pattern 144 according to the level of the lower conductive layer 130. The mask layer 150 is formed on a sidewall of the inner spacer 140 formed on one sidewall of the lower conductive layer 130 and the direct contact DC.

The mask layer 150 may be a material layer for protecting the inner spacer 140 according to the level of the lower conductive layer 130. In some example embodiments, the mask layer 150 may use a spin-on-hard mask technique.

Referring to FIG. 9D, the left drawing of FIG. 9D may be an enlarged view of a portion corresponding to the dashed line region indicated by “FX” in the right drawing. The inner spacer 140 formed on sidewalls of the intermediate conductive layer 132, the upper conductive layer 134, and the insulating capping pattern 136 is etched using the mask layer (150 in FIG. 9C) as a mask. Thereafter, the mask layer 150 is removed.

In this case, the depletion stopping layer 142 may be formed only on the direct contact DC and the sidewall of the lower conductive layer 130. The inner spacer 140 may be formed on one sidewall of the depletion stopping layer 142 formed on the sidewalls of the direct contact DC and the lower conductive layer 130.

In the first horizontal direction (the X direction), one sidewall of the depletion stopping layer 142 may be located on an inner side relative to one sidewall of the upper conductive layer 134 and the insulating capping pattern 136. Widths of the intermediate conductive layer 132, the upper conductive layer 134, and the insulating capping pattern 136 in the first horizontal direction (the X direction) may be greater than those of the direct contact DC and the lower conductive layer 130.

Referring to FIG. 9E, the left drawing of FIG. 9E may be an enlarged view of a portion corresponding to the dashed line region indicated by “GX” in the right drawing. The passivation layer 138 is formed on one sidewall of the inner spacer 140 formed on one sidewalls of the lower conductive layer 130 and the direct contact DC, one sidewall of the intermediate conductive layer 132, one sidewall of the upper conductive layer 134, and one sidewall and upper surface of the insulating capping pattern 136.

The passivation layer 138 may also be formed on the upper surface of the buffer layer 122 or the upper surface of the gap-fill insulating pattern 144. The passivation layer 138 may be formed to extend non-linearly in the vertical direction (the Z direction) from an upper portion of one sidewall of the upper conductive layer 134 of the bit line BL. The passivation layer 138 may be formed to be curved on the uppermost surface of the inner spacer 140. In some example embodiments, the passivation layer 138 may include a silicon nitride layer.

Subsequently, the intermediate spacer (152 in FIGS. 6A and 6B) and the outer spacer (154 in FIGS. 6A and 6B) are formed on the inner spacer 140 formed on the sidewalls of the direct contact DC and the bit line BL, thereby forming the spacer structure (SP1 in FIGS. 6A and 6B).

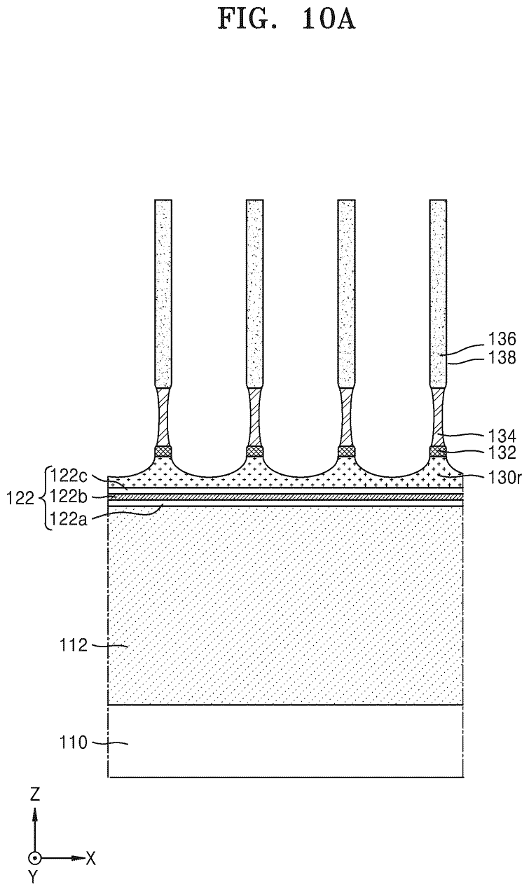

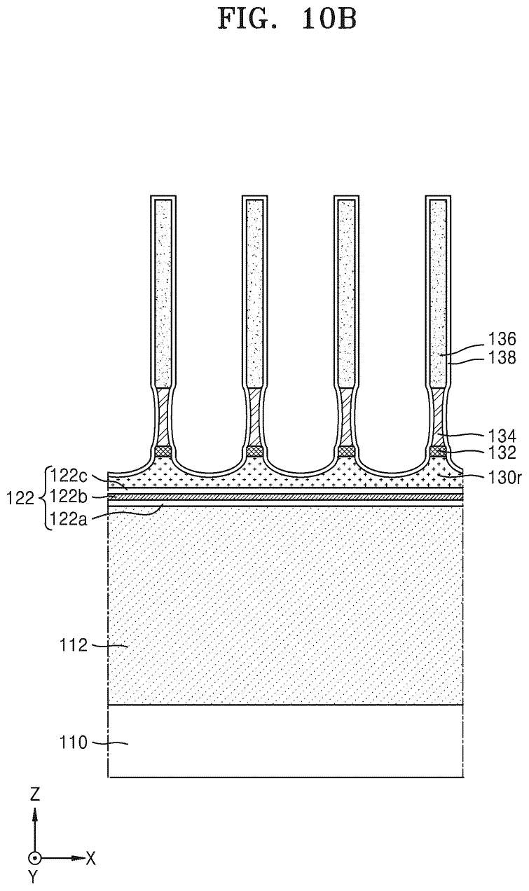

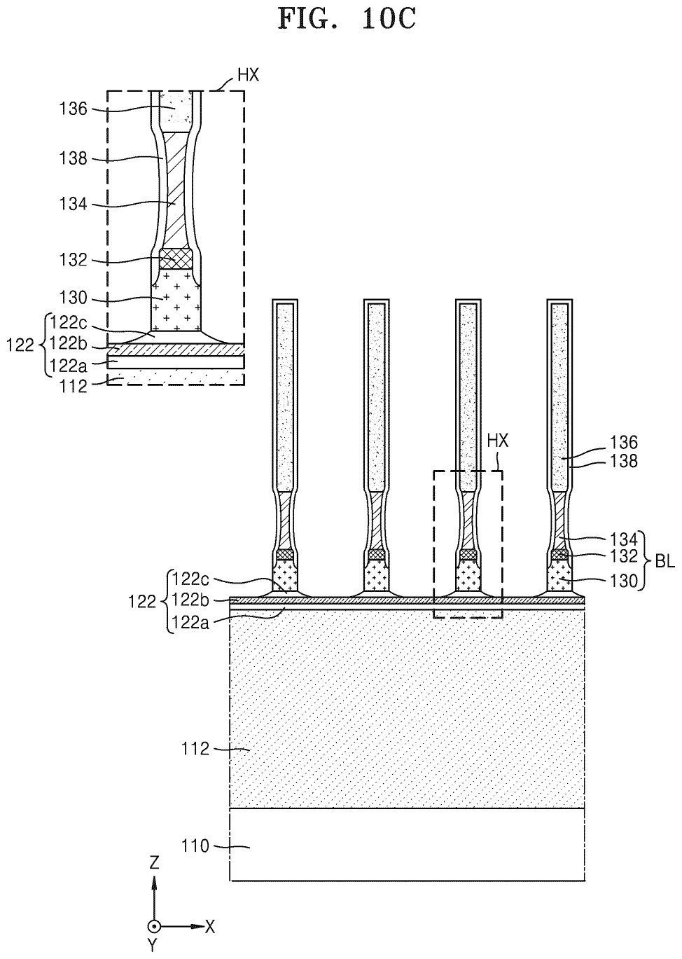

FIGS. 10A to 10C are cross-sectional views illustrating a method of manufacturing a portion of a semiconductor device according to an example embodiment.

For example, FIGS. 10A to 10C may be cross-sectional views illustrating a method of manufacturing some components of the first cell edge region UBE-1 corresponding to the cross-section taken along line B-B′ of FIG. 3. FIGS. 10A to 10C may be cross-sectional views of a manufacturing process corresponding to FIGS. 7A to 7C.

FIGS. 10A to 10C may be cross-sectional views illustrating a method of manufacturing the first cell edge region UBE-1 of the semiconductor device EX1 shown in FIGS. 4A and 4B and 7A to 7E. With reference to FIGS. 10A to 10C, the description given above with reference to FIGS. 7A to 7C is briefly given or omitted.

Referring to FIG. 10A, FIG. 10A may be a cross-sectional view of a manufacturing process corresponding to FIG. 7A. The device isolation film 112 and the buffer layer 122 may be formed on the substrate 110. In some example embodiments, the buffer layer 122 may include the first silicon oxide film 122a, the silicon nitride film 112b, and the second silicon oxide film 122c on the substrate 110. In some example embodiments, the buffer layer 122 may include a single film of the first silicon oxide film 122a or the second silicon oxide film 122c or a single film of the silicon nitride film 112b.

The lower conductive material layer 130r is formed on the buffer layer 122, and the intermediate conductive layer 132, the upper conductive layer 134, and the insulating capping pattern 136 are formed on the lower conductive material layer 130r.

For example, after sequentially forming the intermediate conductive material layer, the upper conductive material layer, and the insulating capping material layer on the lower conductive material layer 130r, a mask pattern is formed on the insulating capping material layer by using a photolithography process.

Subsequently, only the insulating capping material layer, the upper conductive material layer, and the intermediate conductive material layer are etched using the mask pattern as an etch mask. In this case, the lower conductive material layer 130r is left, and the intermediate conductive layer 132, the upper conductive layer 134, and the insulating capping pattern 136 are formed on the lower conductive material layer 130r.

During etching using the mask pattern, the uppermost surface of the lower conductive material layer 130r may be formed in a curved shape. In some example embodiments, the lower conductive material layer 130r includes a polysilicon film doped with impurities.

During etching using the mask pattern, a central portion of the upper conductive layer 134 may be over-etched. The central portion of the upper conductive layer 134 may have a width less than those of upper and lower portions thereof. Accordingly, one sidewall of the upper conductive layer 134 may not have a uniform vertical profile. In some example embodiments, the upper conductive layer 134 may include a film including Ti, TiN, TiSiN, tungsten (W), WN, tungsten silicide (WSix), tungsten silicon nitride (WSixNy), ruthenium (Ru), or combinations thereof.

Referring to FIG. 10B, FIG. 10B may be a cross-sectional view of a manufacturing process corresponding to FIG. 7B. The passivation material layer 138r is formed on the lower conductive material layer 130r, the intermediate conductive layer 132, the upper conductive layer 134, and the insulating capping pattern 136. The passivation material layer 138r may be formed on the surface of the lower conductive material layer 130r, the intermediate conductive layer 132, the upper conductive layer 134, the sidewall of the insulating capping pattern 136, and the upper surface of the insulating capping pattern 136. In some example embodiments, passivation material layer 138r includes a silicon nitride layer.

Referring to FIG. 10C, FIG. 10C may be a cross-sectional view of a manufacturing process corresponding to FIG. 7C. The left drawing of FIG. 10C may be an enlarged view of a portion corresponding to the dashed line region indicated by “HX” in the right drawing.

The lower conductive material layer 130r is etched using the insulating capping pattern 136 and the passivation material layer (138r in FIG. 10B) as a mask to form the bit lines BL and the passivation layer 138 on the substrate 110. The bit lines BL may include the lower conductive layer 130, the intermediate conductive layer 132, and the upper conductive layer 134.

During etching to form the bit lines BL, the passivation material layer (138r in FIG. 10B) may serve to protect the upper conductive layer 134. Accordingly, the upper conductive layer 134 may not be cut in the vertical direction (the Z direction). The passivation layer 138 may be formed on the sidewalls of the intermediate conductive layer 132, the upper conductive layer 134, and the insulating capping pattern 136. In some example embodiments, the passivation layer 138 may also be formed on a portion of one sidewall of the uppermost portion of the lower conductive layer 130.

As described above, in the semiconductor device EX1 described above, the upper conductive layer 134 constituting the bit line BL may be protected by the passivation layer 138 in the first cell edge region UBE-1. In addition, in the semiconductor device EX1 described above, the intermediate conductive layer 132 and the upper conductive layer 134 of the bit line BL may be protected by the passivation layer 138 in the first cell edge region UBE-1.

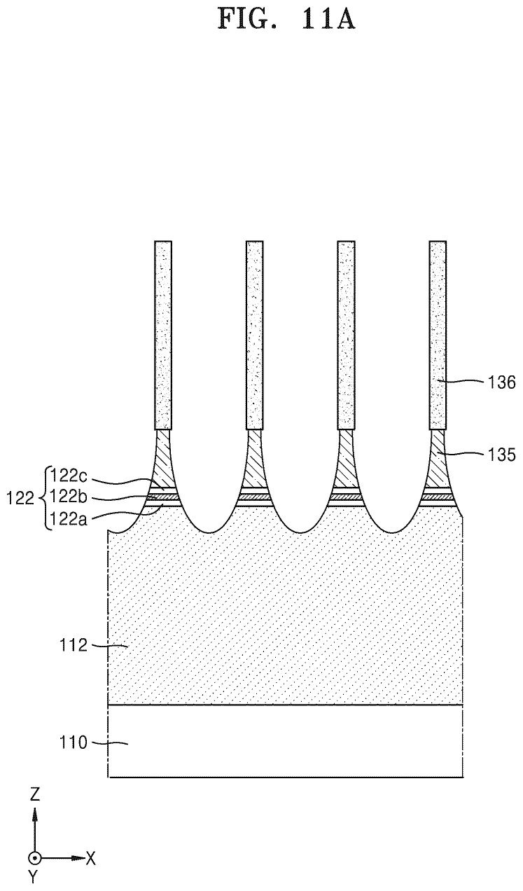

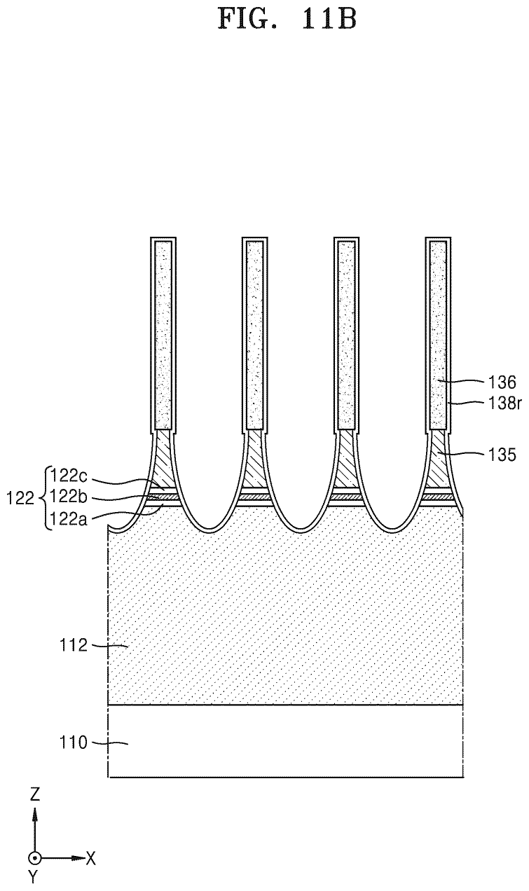

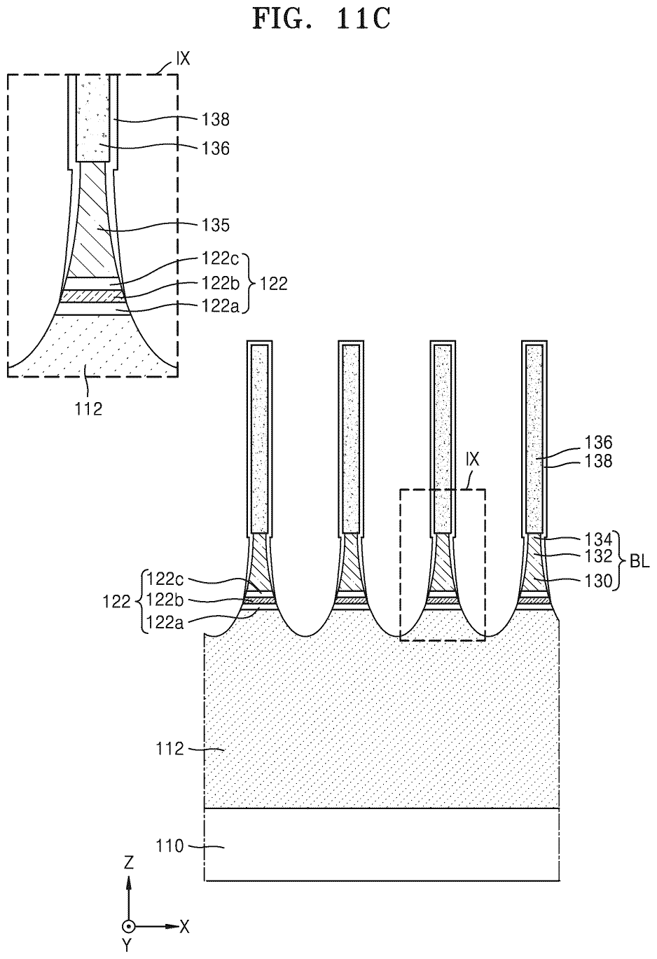

FIGS. 11A to 11C are cross-sectional views illustrating a method of manufacturing a portion of a semiconductor device according to an example embodiment.

For example, FIGS. 11A to 11C may be cross-sectional views illustrating a method of manufacturing some components of the second cell edge region UBE-2 corresponding to a cross-section taken along line C-C′ of FIG. 3. FIGS. 11A to 11C may be cross-sectional views of a manufacturing process corresponding to FIGS. 7A to 7C. FIGS. 11A to 11C may be cross-sectional views of a manufacturing process corresponding to FIGS. 10A to 10C.

FIGS. 11A to 11C may be cross-sectional views illustrating a method of manufacturing the second cell edge region UBE-2 of the semiconductor device EX1 shown in FIGS. 4A and 4B and 7A to 7E. With reference to FIGS. 11A to 11C, the description given above with reference to FIGS. 7A to 7C and 10A to 10C is briefly given or omitted.

Referring to FIG. 11A, FIG. 11A may be a cross-sectional view of a manufacturing process corresponding to FIGS. 7A and 10A. The device isolation film 112 and the buffer layer 122 may be formed on the substrate 110. In some example embodiments, the buffer layer 122 may include the first silicon oxide film 122a, the silicon nitride film 112b, and the second silicon oxide film 122c on the substrate 110. In some example embodiments, the buffer layer 122 may include a single film of the first silicon oxide film 122a or the second silicon oxide film 122c or a single film of the silicon nitride film 112b.

The insulating pattern 135 and the insulating capping pattern 136 are formed on the buffer layer 122. The insulating pattern 135 includes a silicon oxide layer. For example, after an insulating material layer and an insulating capping material layer are formed on the buffer layer 122, a mask pattern is formed on the insulating capping material layer by using a photolithography process. Subsequently, the insulating capping material layer and the insulating material layer are etched using the mask pattern as an etch mask. In this case, the insulating pattern 135 and the insulating capping pattern 136 are formed on the buffer layer 122.

During etching using the mask pattern, the buffer layer 122 may also be etched. During etching using the mask pattern, the uppermost surface of the device isolation film 112 may be formed in a curved shape. During etching using the mask pattern, the width of the insulating pattern 135 may be less than the width of the insulating capping pattern 136.

Referring to FIG. 11B, FIG. 11B may be a cross-sectional view of a manufacturing process corresponding to FIGS. 7B and 10B. The passivation material layer 138r is formed on the insulating pattern 135 and the insulating capping pattern 136. The passivation material layer 138r is formed on the sidewall of the buffer layer 122, the sidewall of the insulating pattern 135, and the upper surface of the device isolation film 112. In some example embodiments, the passivation material layer 138r includes a silicon nitride layer.

Referring to FIG. 11C, FIG. 11C may be a cross-sectional view of a manufacturing process corresponding to FIGS. 7C and 10C. The left drawing of FIG. 11C may be an enlarged view of a portion corresponding to the dashed line region indicated by “IX” in the right drawing.

When the bit line BL of FIGS. 7C and 10C is formed, the passivation material layer (138r of FIG. 10B) and the device isolation film 112 may be etched. When the bit line BL of FIGS. 7C and 10C is formed, the passivation material layer (138 of FIG. 10B) may serve to protect the insulating pattern 135. Accordingly, the insulating pattern 135 may not be cut in the vertical direction (the Z direction).

The passivation layer 138 may be formed on the sidewall of the insulating pattern 135, which is connected to the bit line BL in the first cell edge region UBE-1, and the sidewall of the insulating capping pattern 136. In some example embodiments, the passivation layer 138 may not be formed on the upper surface of the soft capping pattern 136. As described above, in the semiconductor device EX1 described above, the insulating pattern 135 may be protected by the passivation layer 138 in the second cell edge region UBE-2.

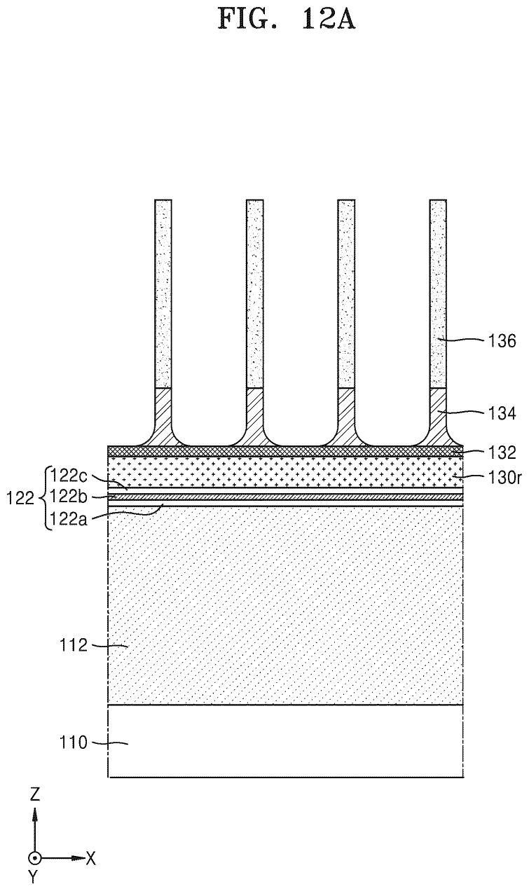

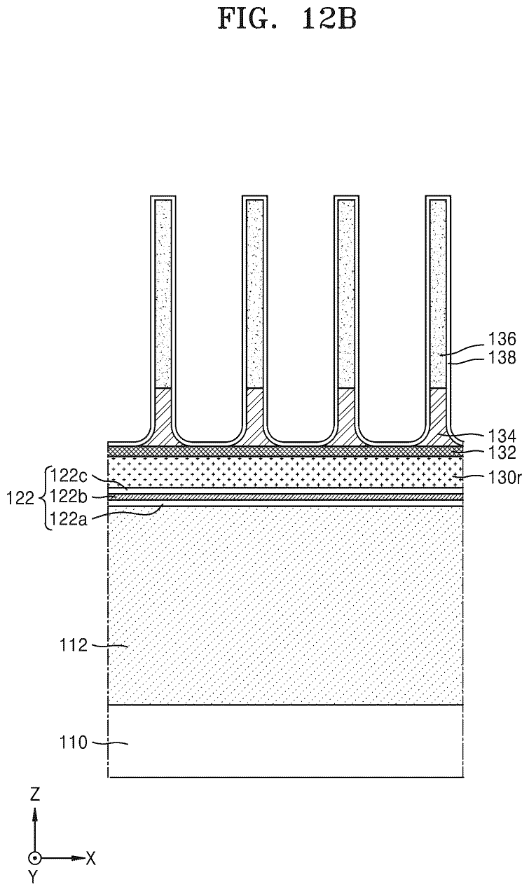

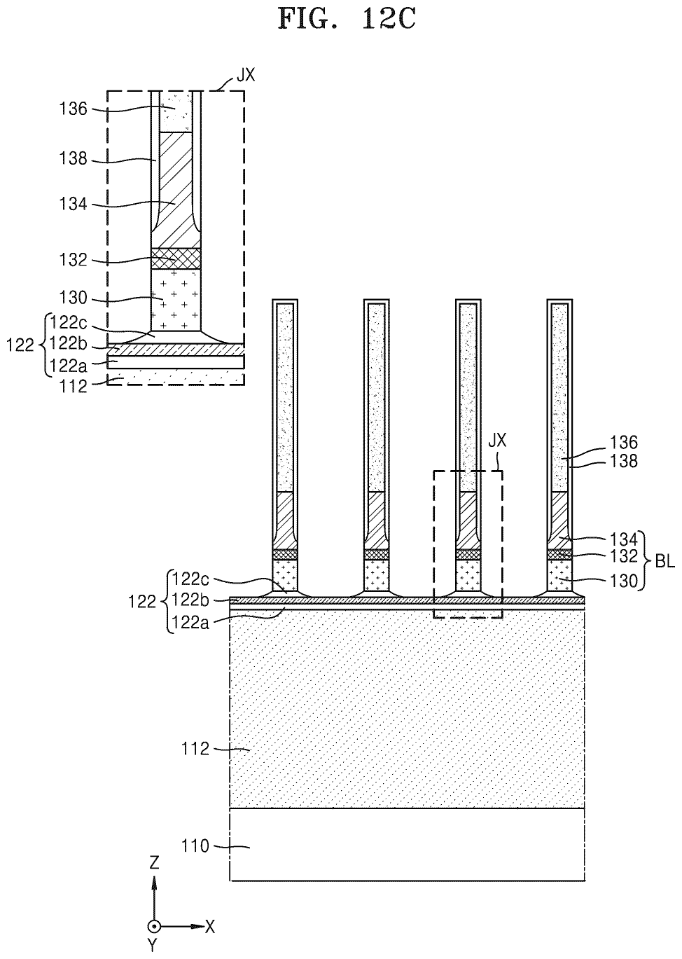

FIGS. 12A to 12C are cross-sectional views illustrating a method of manufacturing a portion of a semiconductor device according to an example embodiment.

For example, FIGS. 12A to 12C may be cross-sectional views illustrating a method of manufacturing some components of the first cell edge region UBE-1 corresponding to the cross-section B-B′ of FIG. 3. FIGS. 12A to 12C may be cross-sectional views of a manufacturing process corresponding to FIGS. 8A to 8C.

FIGS. 12A to 12C may be cross-sectional views illustrating a method of manufacturing the first cell edge region UBE-1 of the semiconductor device EX2 shown in FIGS. 5A and 5B and 8A to 8E. With reference to FIGS. 12A to 10C, the description given above with reference to FIGS. 8A to 8C is briefly given or omitted.

Referring to FIG. 12A, FIG. 12A may be a cross-sectional view of a manufacturing process corresponding to FIG. 8A. A device isolation film 112 and a buffer layer 122 may be formed on the substrate 110. In some example embodiments, the buffer layer 122 may include the first silicon oxide film 122a, the silicon nitride film 112b, and the second silicon oxide film 122c on the substrate 110. In some example embodiments, the buffer layer 122 may include a single film of the first silicon oxide film 122a or the second silicon oxide film 122c or a single film of the silicon nitride film 112b.

The lower conductive material layer 130r is formed on the buffer layer 122, and the intermediate conductive layer 132, the upper conductive layer 134, and the insulating capping pattern 136 are formed on the lower conductive material layer 130r.

For example, after sequentially forming the intermediate conductive material layer, the upper conductive material layer, and the insulating capping material layer on the lower conductive material layer 130r, a mask pattern is formed on the insulating capping material layer by using a photolithography process. Subsequently, only the insulating capping material layer and the upper conductive material layer are etched using the mask pattern as an etch mask.

In this case, the lower conductive material layer 130r and the intermediate conductive material layer 132r are left, and the intermediate conductive layer 132, the upper conductive layer 134, and the insulating capping pattern 136 are formed on the intermediate conductive material layer 132r. An upper portion of the upper conductive layer 134 in the vertical direction (the Z direction) may have a width less than that of a lower portion thereof.

The uppermost surface of the intermediate conductive material layer 132r may be formed in a flat surface shape. In some example embodiments, the lower conductive material layer 130r includes a polysilicon film doped with impurities. The intermediate conductive material layer 132r and the upper conductive layer 134 may include a film including Ti, TiN, TiSiN, tungsten (W), WN, tungsten silicide (WSix), tungsten silicon nitride (WSixNy), ruthenium (Ru), or combinations thereof.

Referring to FIG. 12B, FIG. 12B may be a cross-sectional view of a manufacturing process corresponding to FIG. 8B. The passivation material layer 138r is formed on the intermediate conductive material layer 132r, the upper conductive layer 134, and the insulating capping pattern 136. The passivation material layer 138r may be formed on the surface of the intermediate conductive material layer 132r, the upper conductive layer 134, the sidewall of the insulating capping pattern 136, and the upper surface of the insulating capping pattern 136. In some example embodiments, the passivation material layer 138r includes a silicon nitride layer.

Referring to FIG. 12C, FIG. 12C may be a cross-sectional view of a manufacturing process corresponding to FIG. 8C. The left drawing of FIG. 12C may be an enlarged view of a portion corresponding to the dashed line region indicated by “JX” in the right drawing.

The intermediate conductive material layer 132r and the lower conductive material layer 130r are etched using the insulating capping pattern 136 and the passivation material layer 138r as an etch mask to form the bit lines BL on the substrate 110. The bit lines BL may include the lower conductive layer 130, the intermediate conductive layer 132, and the upper conductive layer 134.

During etching to form the bit lines BL, the passivation material layer 138r may be etched to form the passivation layer 138. The passivation layer 138 may be formed on the sidewall of the upper conductive layer 134, the sidewall of the insulating capping pattern 136, and the upper surface of the insulating capping pattern 136.

During etching for forming the bit lines BL, the passivation material layer (138r in FIG. 12B) may serve to protect the upper conductive layer 134. Accordingly, the upper conductive layer 134 may not be cut in the vertical direction (the Z direction). The passivation layer 138 may be formed on the sidewalls of the upper conductive layer 134 and the insulating capping pattern 136. As described above, in the semiconductor device EX2 described above, the upper conductive layer 134 constituting the bit line BL may be protected by the passivation layer 138 in the first cell edge region UBE-1.

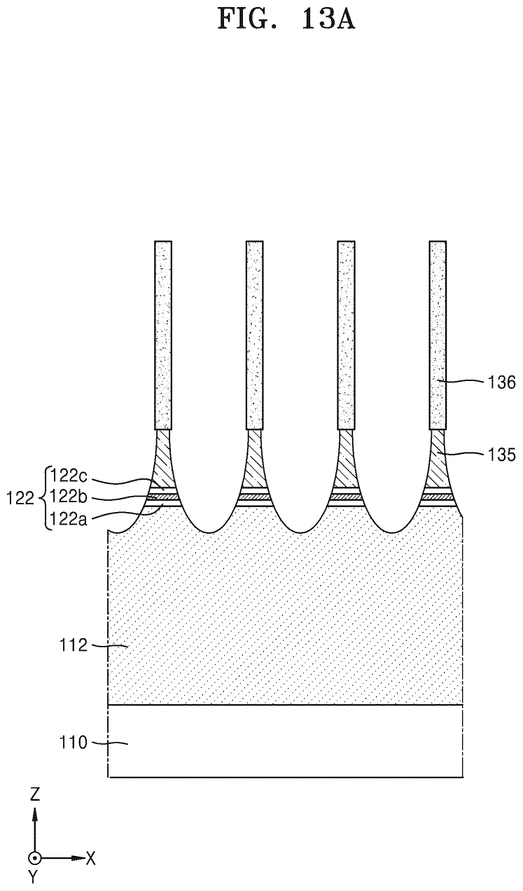

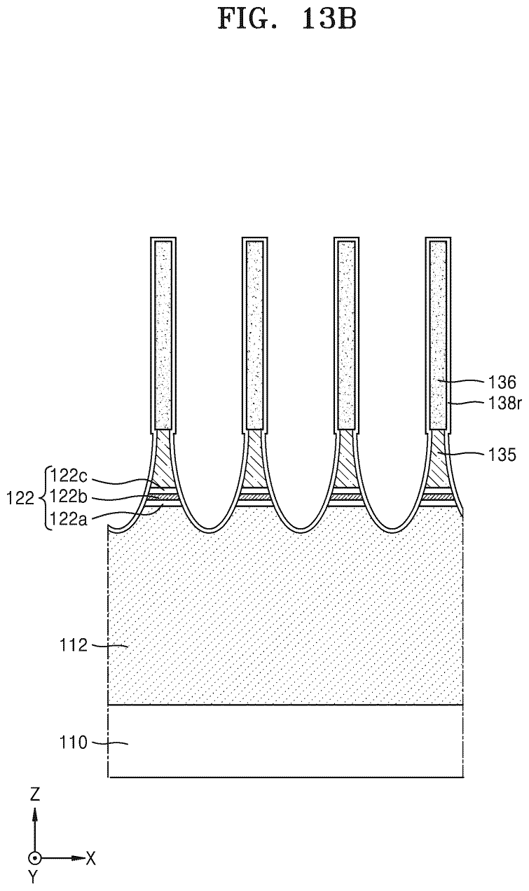

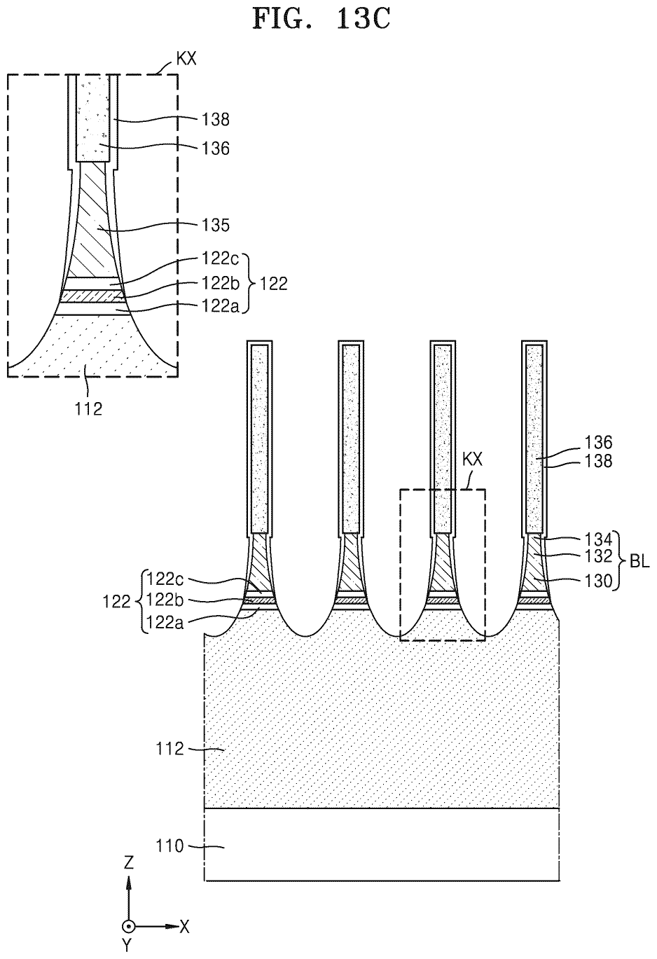

FIGS. 13A to 13C are cross-sectional views illustrating a method of manufacturing a portion of a semiconductor device according to an example embodiment.

For example, FIGS. 13A to 13C may be cross-sectional views illustrating a method of manufacturing some components of the second cell edge region UBE-2 corresponding to the cross-section taken along line C-C′ of FIG. 3. FIGS. 13A to 13C may be cross-sectional views of a manufacturing process corresponding to FIGS. 8A to 8C. FIGS. 13A to 13C may be cross-sectional views of a manufacturing process corresponding to FIGS. 12A to 12C, respectively.

FIGS. 13A to 13C may be cross-sectional views illustrating a method of manufacturing the second cell edge region UBE-2 of the semiconductor device EX2 shown in FIGS. 5A and 5B and 8A to 8E. With reference to FIGS. 13A to 13C, the description given above with reference to FIGS. 8A to 8C and 12A to 12C is briefly given or omitted.

Referring to FIG. 13A, FIG. 13A may be a cross-sectional view of a manufacturing process corresponding to FIGS. 8A and 12A. The device isolation film 112 and the buffer layer 122 may be formed on the substrate 110. In some example embodiments, the buffer layer 122 may include a first silicon oxide film 122a, a silicon nitride film 112b, and a second silicon oxide film 122c on the substrate 110. In some embodiments, the buffer layer 122 may be a single layer of the first silicon oxide film 122a or the second silicon oxide film 122c or a single layer of the silicon nitride film 112b.

The insulating pattern 135 and the insulating capping pattern 136 are formed on the buffer layer 122. The insulating pattern 135 includes a silicon oxide layer. For example, after an insulating material layer and an insulating capping material layer are formed on the buffer layer 122, a mask pattern is formed on the insulating capping material layer by using a photolithography process. Subsequently, the insulating capping material layer and the insulating material layer are etched using the mask pattern as an etch mask. In this case, the insulating pattern 135 and the insulating capping pattern 136 are formed on the buffer layer 122.

During etching using the mask pattern, the buffer layer 122 may also be etched. During etching using the mask pattern, the uppermost surface of the device isolation film 112 may be formed in a curved shape. During etching using the mask pattern, the width of the insulating pattern 135 may be less than the width of the insulating capping pattern 136.

Referring to FIG. 13B, FIG. 13B may be a cross-sectional view of a manufacturing process corresponding to FIGS. 8B and 12B. The passivation material layer 138r is formed on the insulating pattern 135 and the insulating capping pattern 136. The passivation material layer 138r is formed on the sidewall of the buffer layer 122, the sidewall of the insulating pattern 135, and the upper surface of the device isolation film 112. In some example embodiments, the passivation material layer 138r includes a silicon nitride layer.

Referring to FIG. 13C, FIG. 13C may be a cross-sectional view of a manufacturing process corresponding to FIGS. 8C and 12C. The left drawing of FIG. 13C may be an enlarged view of a portion corresponding to the dashed line region indicated by “KX” in the right drawing.

When the bit line BL of FIGS. 8C and 12C is formed, the passivation material layer (138r of FIG. 13B) and the device isolation film 112 may be etched. When the bit line BL of FIGS. 8C and 12C is formed, the passivation material layer (138 of FIG. 13B) may serve to protect the insulating pattern 135. Accordingly, the insulating pattern 135 may not be cut in the vertical direction (the Z direction).

The passivation layer 138 may be formed on the sidewall of the insulating pattern 135 and the sidewall of the insulating capping pattern 136. In some example embodiments, the passivation layer 138 may not be formed on the upper surface of the soft capping pattern 136. As described above, in the semiconductor device EX2 described above, the insulating pattern 135 in the second cell edge region UBE-2 may be protected by the passivation layer 138.

While the inventive concepts have been particularly shown and described with reference to some example embodiments thereof, it will be understood that various changes in form and details may be made therein without departing from the spirit and scope of the following claims.

What is claimed is:

1. A semiconductor device comprising:
a substrate;
a word line extending on the substrate in a first horizontal direction;
a bit line extending on the substrate in a second horizontal direction perpendicular to the first horizontal direction; and
a spacer structure on one sidewall of the bit line,
wherein the bit line includes a lower conductive layer, an intermediate conductive layer, and an upper conductive layer stacked in a vertical direction on the substrate, and
the spacer structure includes,
a depletion stopping layer on one sidewall of the lower conductive, extending in the vertical direction, and including a material layer having an interfacial trap density less than an interfacial trap density of a silicon nitride layer, and
an inner spacer extending in the vertical direction and on one sidewall of the depletion stopping layer.

2. The semiconductor device of claim 1, wherein the lower conductive layer includes a polysilicon layer doped with impurities, and the depletion stopping layer includes a silicon oxide layer.

3. The semiconductor device of claim 1, wherein the inner spacer includes a silicon oxide layer or a carbon-containing oxide layer.

4. The semiconductor device of claim 1, wherein the intermediate conductive layer includes a barrier metal layer, and the upper conductive layer includes a metal layer.

5. The semiconductor device of claim 1, wherein the spacer structure includes:
an intermediate spacer on one sidewall of the inner spacer and extending in the vertical direction; and
an outer spacer on one sidewall of the intermediate spacer and extending in the vertical direction.

6. The semiconductor device of claim 5, wherein the intermediate spacer includes a silicon oxide layer, and the outer spacer includes a silicon nitride layer.

7. The semiconductor device of claim 1, wherein a portion an upper surface the substrate defines a direct contact hole, the substrate further includes an active region in the direct contact hole, the bit line contacts the active region in the direct contact hole, and a gap-fill insulating pattern in the direct contact hole and on one sidewall of the space structure.

8. The semiconductor device of claim 1, wherein a portion an upper surface the substrate defines a buried contact hole, the substrate further includes an active region in the buried contact hole, and a buried contact plug is in contact with the active region in the buried contact hole.

9. A semiconductor device comprising:
a substrate;
a word line extending on the substrate in a first horizontal direction;
a bit line extending on the substrate in a second horizontal direction perpendicular to the first horizontal direction; and
a spacer structure on one sidewall of the bit line,
wherein the bit line includes a lower conductive layer, an intermediate conductive layer, and an upper conductive layer stacked in a vertical direction on the substrate, and
the spacer structure includes,
a depletion stopping layer on one sidewall of the lower conductive layer, extending in the vertical direction, and including a material layer having an interfacial trap density less than an interfacial trap density of a silicon nitride layer,
a passivation layer extending in the vertical direction and on a portion of one sidewall of the upper conductive layer, and
an inner spacer on one sidewall of the passivation layer and on one sidewall of the depletion stopping layer, and extending in the vertical direction.

10. The semiconductor device of claim 9, wherein the inner spacer is continuously on an upper portion of one sidewall of the bit line.

11. The semiconductor device of claim 9, further comprising:
a metal oxide layer on one of sidewalls of the upper conductive layer and the intermediate conductive layer.

12. The semiconductor device of claim 9, wherein the passivation layer is further on one sidewall of an upper portion of the lower conductive layer and one sidewall of the intermediate conductive layer.

13. The semiconductor device of claim 9, wherein the spacer structure includes:
an intermediate spacer on one sidewall of the inner spacer and extending in the vertical direction; and
an outer spacer on one sidewall of the intermediate spacer and extending in the vertical direction.

14. The semiconductor device of claim 9, wherein
the substrate includes a cell center region and a cell edge region surrounding the cell center region when viewed in a plan view, and
the passivation layer is on at least one sidewall of the intermediate conductive layer or the upper conductive layer of the bit line in the cell edge region.

15. The semiconductor device of claim 9, wherein
the substrate includes a cell center region and a cell edge region surrounding the cell center region when view in a plan view, and
the passivation layer is on one sidewall of the upper conductive layer of the bit line in the cell edge region.

16. The semiconductor device of claim 9, wherein
the substrate includes a cell center region and a cell edge region surrounding the cell center region when viewed in a plan view,
the cell edge region includes a first cell edge region in which the bit line extends in the second horizontal direction and a second cell edge region in which the bit line does not extend in the second horizontal direction, and
the passivation layer is on one sidewall of an insulating pattern, which is connected to the bit line in the first cell edge region, in the second cell edge region.

17. A semiconductor device comprising:
a substrate;
a word line extending on the substrate in a first horizontal direction;
a bit line extending on the substrate in a second horizontal direction perpendicular to the first horizontal direction; and
a spacer structure on one sidewall of the bit line,
wherein the bit line includes a lower conductive layer, an intermediate conductive layer, and an upper conductive layer stacked in a vertical direction on the substrate, and
the spacer structure includes,
a depletion stopping layer on one sidewall of the lower conductive layer, extending in the vertical direction, and including a material layer having an interfacial trap density less than an interfacial trap density of a silicon nitride layer,
an inner spacer extending in the vertical direction and on one sidewall of the depletion stopping layer, and
a passivation layer extending in the vertical direction and on one sidewall of the inner spacer, one sidewall of the intermediate conductive layer, and one sidewall of the upper conductive layer.

18. The semiconductor device of claim 17, wherein the passivation layer extends nonlinearly in the vertical direction.

19. The semiconductor device of claim 17, wherein one sidewall of the depletion stopping layer is located on an inner side relative to one sidewalls of the intermediate conductive layer and the upper conductive layer in the first horizontal direction.

20. The semiconductor device of claim 17, wherein the spacer structure includes:
an intermediate spacer on one sidewall of the passivation layer and extending in the vertical direction; and
an outer spacer on one sidewall of the intermediate spacer and extending in the vertical direction.
